(19) United States
(12) Patent Application Publication
(10) Pub. No.: US 2015/0179941 A1
(43) Pub. Date: Jun. 25, 2015

(54) DIAMINE DERIVATIVE, MATERIAL FOR ORGANIC ELECTROLUMINESCENCE DEVICE AND ORGANIC ELECTROLUMINESCENCE DEVICE

(71) Applicant: SAMSUNG DISPLAY CO., LTD., Yongin-City (JP)

(72) Inventor: Yasuo MIYATA, Yokohama (JP)

(21) Appl. No.: 14/576,913

(22) Filed: Dec. 19, 2014

(30) Foreign Application Priority Data
Dec. 20, 2013 (JP) 2013-264178

(51) Int. Cl. H01L 51/00

(52) U.S. Cl. CPC H01L 51/006; H01L 51/0061; H01L 51/0072; H01L 51/5088

(57) ABSTRACT

A diamine derivative including an octahydroanthracene group is represented by the following Formula (1):

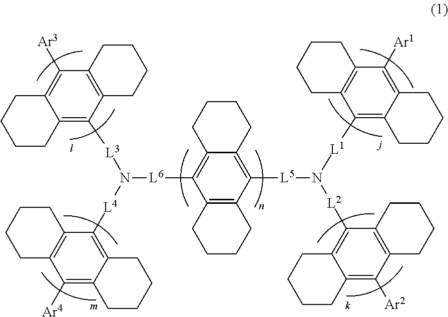

wherein, in Formula 1, Ar¹ to Ar⁴ are independently hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group or a substituted or unsubstituted trialkylsilyl group, j, k, l, m and n are independently 0 or 1, where the relation of j+k+l+m+n≧1 is satisfied, and L¹ to L⁶ are independently a single bond, a substituted or unsubstituted arylene group or a substituted or unsubstituted heteroarylene group.

### CROSS-REFERENCE TO RELATED APPLICATION

Japanese Patent Application No. 2013-264178, filed on Dec. 20, 2013, in the Japanese Patent Office, and entitled: “Diamine Derivative, Material for Organic Electroluminescence Device and Organic Electroluminescence Device,” is incorporated by reference herein in its entirety.

### BACKGROUND

1. Field

Embodiments relate to a diamine derivative, a material for an organic electroluminescence device and an organic electroluminescence device.

2. Description of the Related Art

In recent years, organic electroluminescence (EL) displays, which are one type of image display, have been actively developed. Unlike a liquid crystal display and the like, the organic EL display is a self-luminescent display. In the organic EL display, holes and electrons injected from an anode and a cathode are recombined in an emission layer such that a light-emitting material including an organic compound of the emission layer emits light, thereby providing a display.

An organic electroluminescence device (hereinafter referred to as an organic EL device) including a plurality of layers having different properties has been suggested, and the organic EL device includes an emission layer and a layer transporting carriers such as holes or electrons to the emission layer.

### SUMMARY

Embodiments are directed to a diamine derivative including an octahydroanthracene group, the diamine derivative being represented by the following Formula (1):

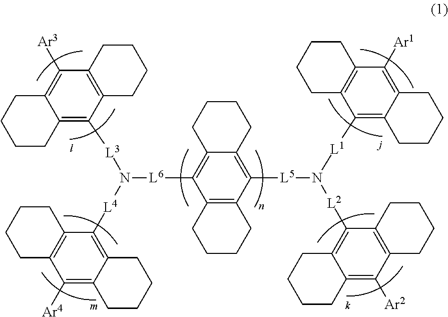

In the above Formula (1), Ar¹ to Ar⁴ are hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group,

j, k, l, m and n are independently 0 or 1, where the relation of j+k+l+m+n≧1 is satisfied, and

L¹ to L⁶ are independently a single bond, a substituted or unsubstituted aryl group or a substituted or unsubstituted heteroaryl group.

The diamine derivative may be a compound represented by the following Formula (2):

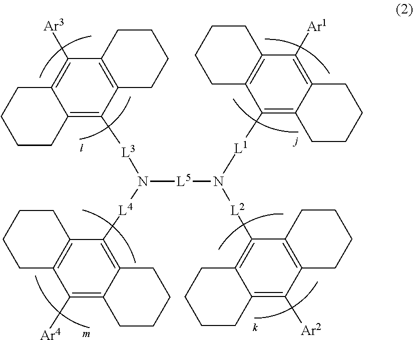

In the above Formula (2),

Ar¹ to Ar⁴ are hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group,

j, k, l, and m are independently 0 or 1, where the relation of j+k+l+m≧1 is satisfied, and

L¹ to L⁵ are independently a single bond, a substituted or unsubstituted aryl group or a substituted or unsubstituted heteroaryl group.

The diamine derivative may be a compound represented by the following Formula (3):

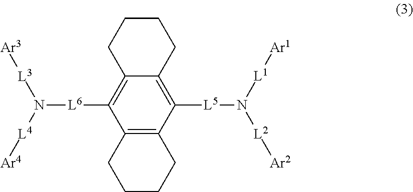

In the above Formula (3), Ar¹ to Ar⁴ are hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group, and

L¹ to L⁶ are independently a single bond, a substituted or unsubstituted aryl group or a substituted or unsubstituted heteroaryl group.

Ar¹ may equal Ar³, Ar² may equal Ar⁴, L¹ may equal L³, and L² may equal L⁴.

Ar¹ may equal Ar², Ar³ may equal Ar⁴, L¹ may equal L², and L³ may equal L⁴.

Ar¹, Ar², Ar³, and Ar⁴ may be equal, and L¹, L², L³, and L⁴ may be equal.

L⁵ may be equal to L⁶.

j may be equal to l, and k may be equal to m.

j may be equal to k, and l may be equal to m.

Ar¹ to Ar⁴ may be a substituted or unsubstituted aryl group having 6 to 18 carbon atoms, a substituted or unsubstituted carbazolyl group, a substituted or unsubstituted benzofuryl group or a substituted or unsubstituted dibenzothienyl group.

L¹ to L⁶ may be independently a single bond or a substituted or unsubstituted aryl group having 6 to 12 carbon atoms.

L¹ to L⁵ may be independently a single bond or a substituted or unsubstituted aryl group having 6 to 12 carbon atoms.

The diamine derivative may be one of the following Compounds 1 to 55.

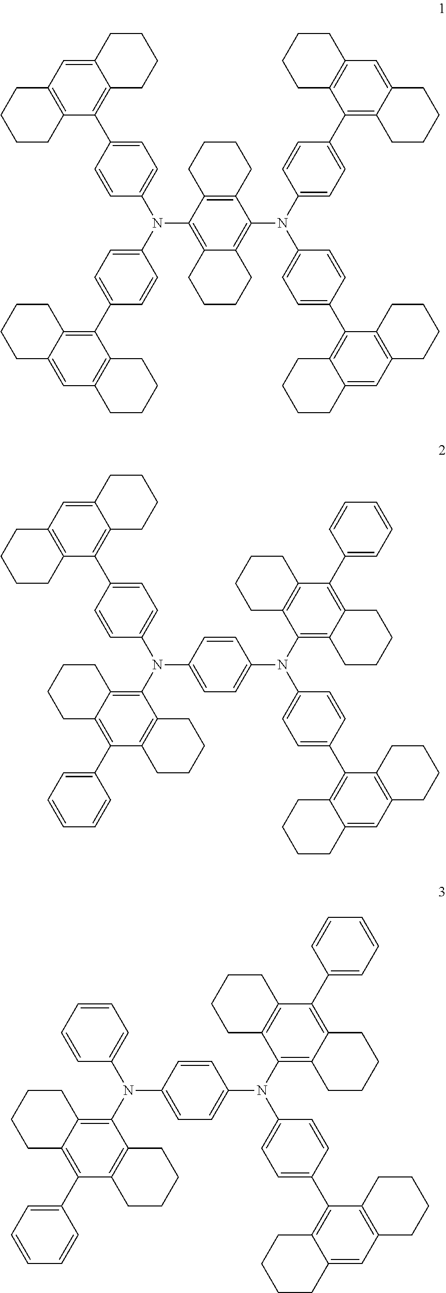 [SMILES: c1cc(N(c2ccc(-c3c4c(cc5c3CCCC5)CCCC4)cc2)c2c3c(c(N(c4ccc(-c5c6c(cc7c5CCCC7)CCCC6)cc4)c4ccc(-c5c6c(cc7c5CCCC7)CCCC6)cc4)c4c2CCCC4)CCCC3)ccc1-c1c2c(cc3c1CCCC3)CCCC2 ; c1ccc(-c2c3c(c(N(c4ccc(-c5c6c(cc7c5CCCC7)CCCC6)cc4)c4ccc(N(c5ccc(-c6c7c(cc8c6CCCC8)CCCC7)cc5)c5c6c(c(-c7ccccc7)c7c5CCCC7)CCCC6)cc4)c4c2CCCC4)CCCC3)cc1 ; c1ccc(-c2c3c(c(N(c4ccccc4)c4ccc(N(c5ccc(-c6c7c(cc8c6CCCC8)CCCC7)cc5)c5c6c(c(-c7ccccc7)c7c5CCCC7)CCCC6)cc4)c4c2CCCC4)CCCC3)cc1]

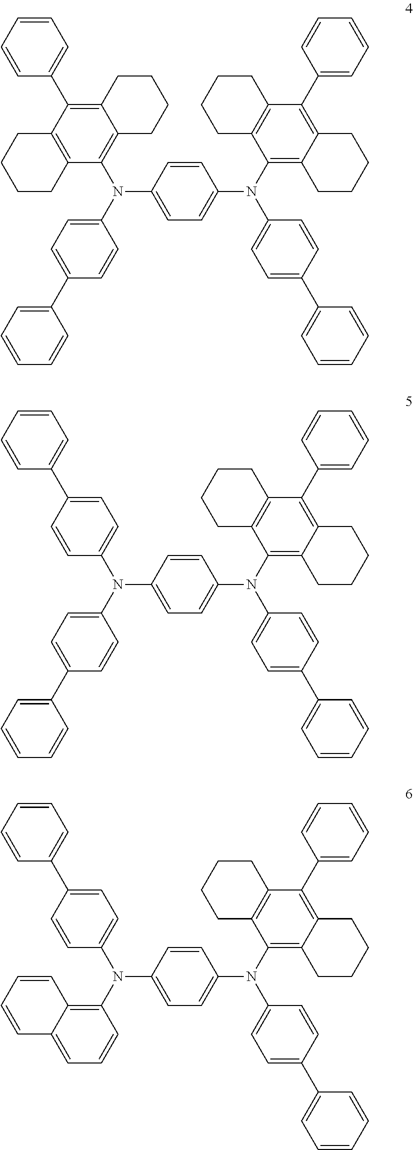

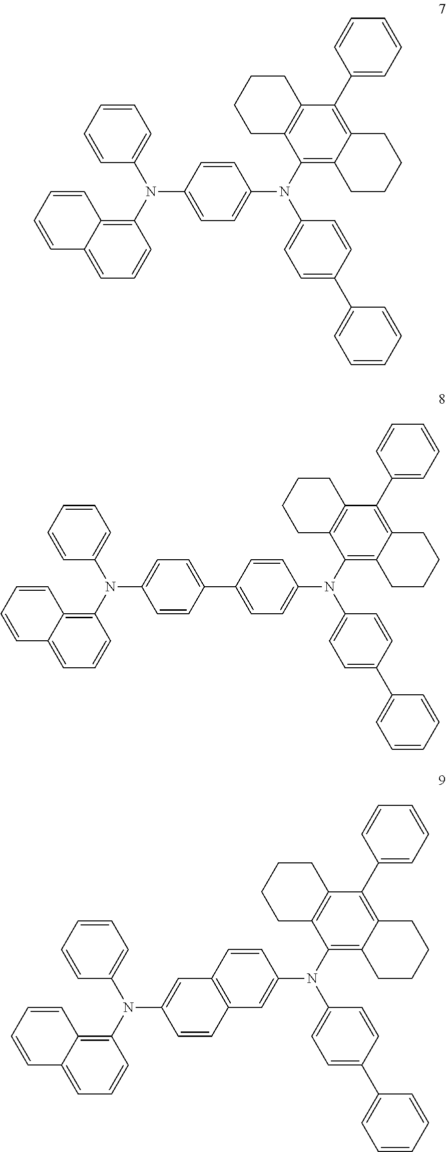 [SMILES: c1ccc(-c2ccc(N(c3ccc(N(c4ccccc4)c4cccc5ccccc45)cc3)c3c4c(c(-c5ccccc5)c5c3CCCC5)CCCC4)cc2)cc1 ; c1ccc(-c2ccc(N(c3ccc(-c4ccc(N(c5ccccc5)c5cccc6ccccc56)cc4)cc3)c3c4c(c(-c5ccccc5)c5c3CCCC5)CCCC4)cc2)cc1 ; c1ccc(-c2ccc(N(c3ccc4cc(N(c5ccccc5)c5cccc6ccccc56)ccc4c3)c3c4c(c(-c5ccccc5)c5c3CCCC5)CCCC4)cc2)cc1]

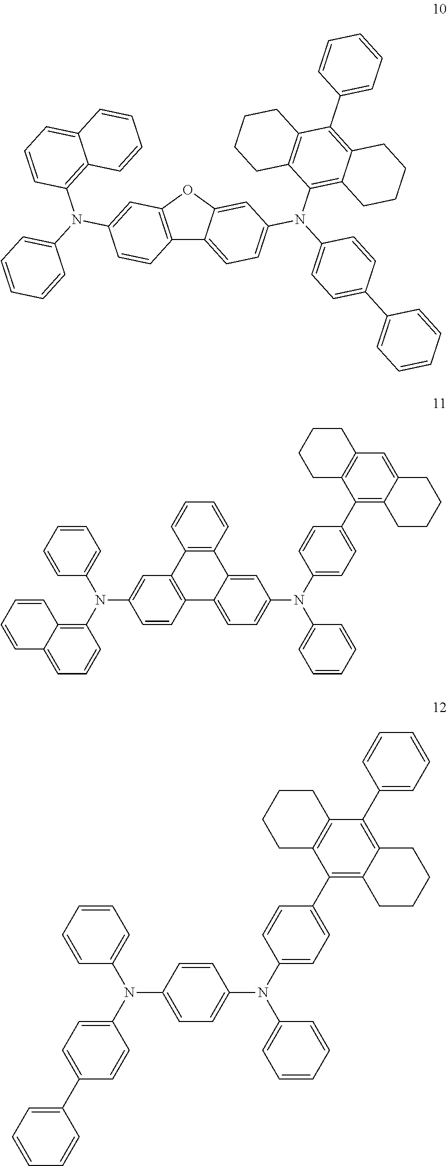 [SMILES: c1ccc(-c2ccc(N(c3ccc4c(c3)oc3cc(N(c5ccccc5)c5cccc6ccccc56)ccc34)c3c4c(c(-c5ccccc5)c5c3CCCC5)CCCC4)cc2)cc1 ; c1ccc(N(c2ccc(-c3c4c(cc5c3CCCC5)CCCC4)cc2)c2ccc3c4ccc(N(c5ccccc5)c5cccc6ccccc56)cc4c4ccccc4c3c2)cc1 ; c1ccc(-c2ccc(N(c3ccccc3)c3ccc(N(c4ccccc4)c4ccc(-c5c6c(c(-c7ccccc7)c7c5CCCC7)CCCC6)cc4)cc3)cc2)cc1]

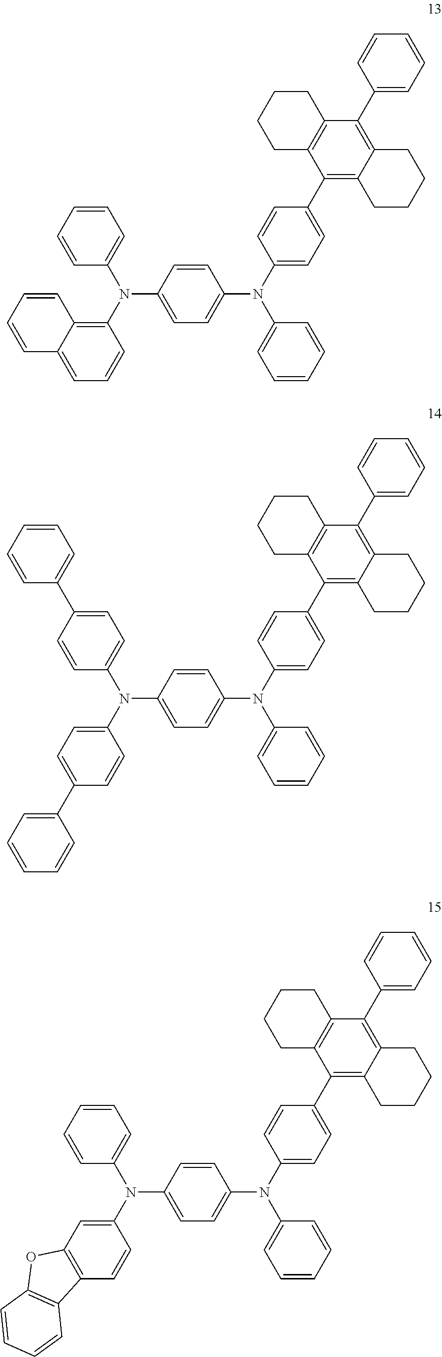 [SMILES: c1ccc(-c2c3c(c(-c4ccc(N(c5ccccc5)c5ccc(N(c6ccccc6)c6cccc7ccccc67)cc5)cc4)c4c2CCCC4)CCCC3)cc1 ; c1ccc(-c2ccc(N(c3ccc(-c4ccccc4)cc3)c3ccc(N(c4ccccc4)c4ccc(-c5c6c(c(-c7ccccc7)c7c5CCCC7)CCCC6)cc4)cc3)cc2)cc1 ; c1ccc(-c2c3c(c(-c4ccc(N(c5ccccc5)c5ccc(N(c6ccccc6)c6ccc7c(c6)oc6ccccc67)cc5)cc4)c4c2CCCC4)CCCC3)cc1]

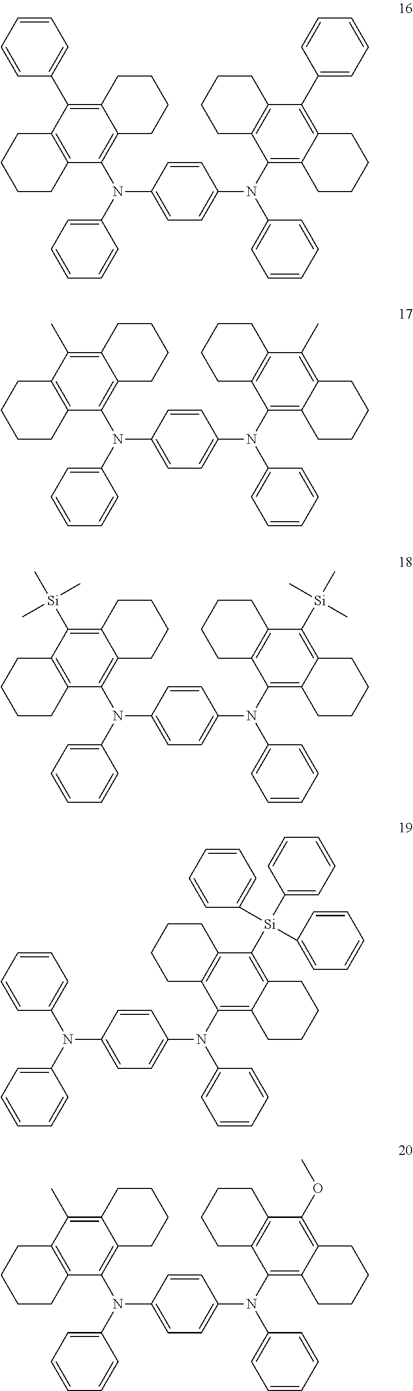

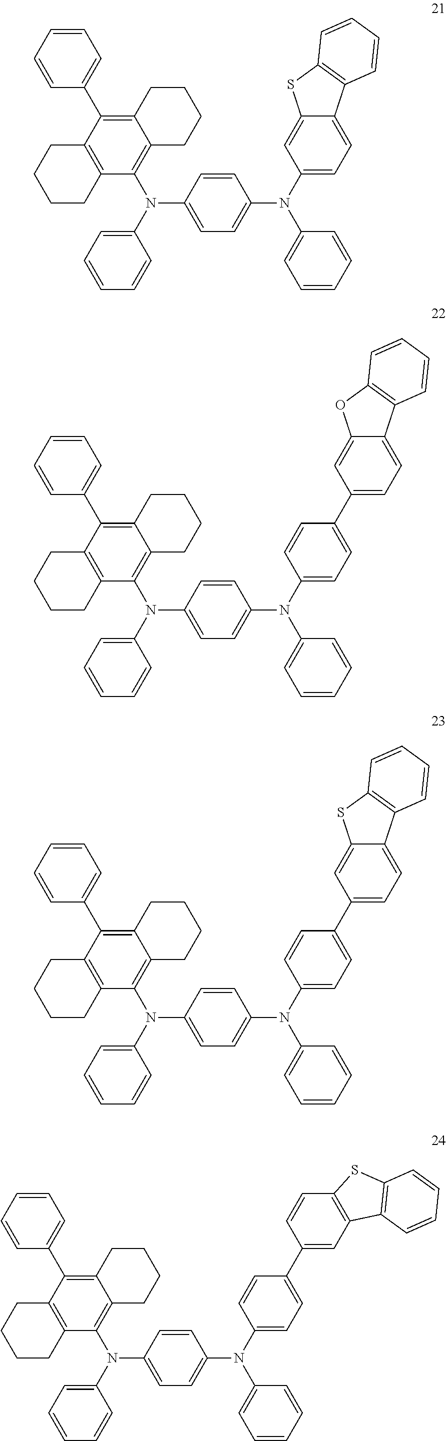 [SMILES: c1ccc(-c2c3c(c(N(c4ccccc4)c4ccc(N(c5ccccc5)c5ccc6c(c5)sc5ccccc56)cc4)c4c2CCCC4)CCCC3)cc1 ; c1ccc(-c2c3c(c(N(c4ccccc4)c4ccc(N(c5ccccc5)c5ccc(-c6ccc7c(c6)oc6ccccc67)cc5)cc4)c4c2CCCC4)CCCC3)cc1 ; c1ccc(-c2c3c(c(N(c4ccccc4)c4ccc(N(c5ccccc5)c5ccc(-c6ccc7c(c6)sc6ccccc67)cc5)cc4)c4c2CCCC4)CCCC3)cc1 ; c1ccc(-c2c3c(c(N(c4ccccc4)c4ccc(N(c5ccccc5)c5ccc(-c6ccc7sc8ccccc8c7c6)cc5)cc4)c4c2CCCC4)CCCC3)cc1]

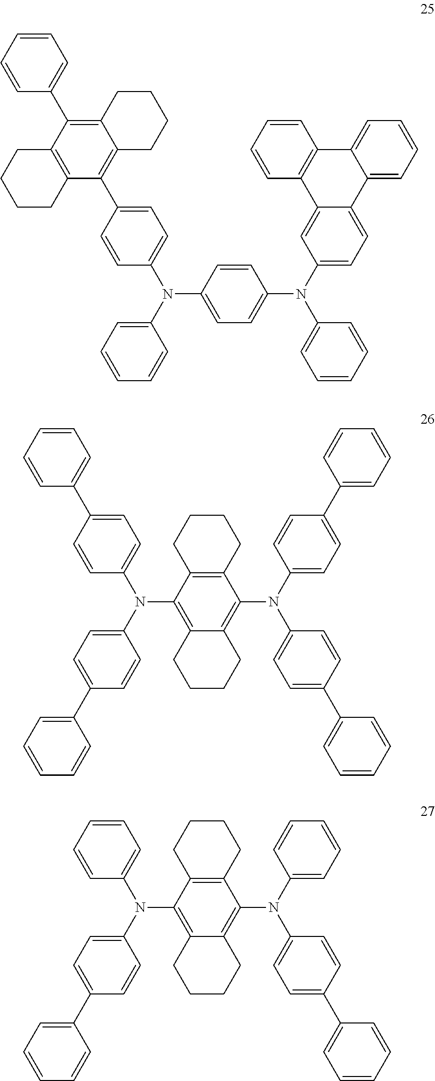 [SMILES: c1ccc(-c2c3c(c(-c4ccc(N(c5ccccc5)c5ccc(N(c6ccccc6)c6ccc7c8ccccc8c8ccccc8c7c6)cc5)cc4)c4c2CCCC4)CCCC3)cc1 ; c1ccc(-c2ccc(N(c3ccc(-c4ccccc4)cc3)c3c4c(c(N(c5ccc(-c6ccccc6)cc5)c5ccc(-c6ccccc6)cc5)c5c3CCCC5)CCCC4)cc2)cc1 ; c1ccc(-c2ccc(N(c3ccccc3)c3c4c(c(N(c5ccccc5)c5ccc(-c6ccccc6)cc5)c5c3CCCC5)CCCC4)cc2)cc1]

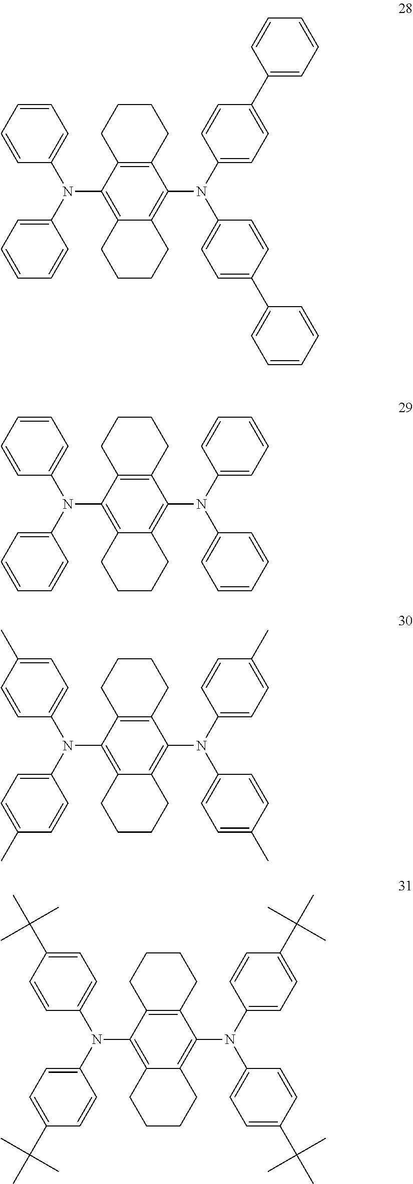

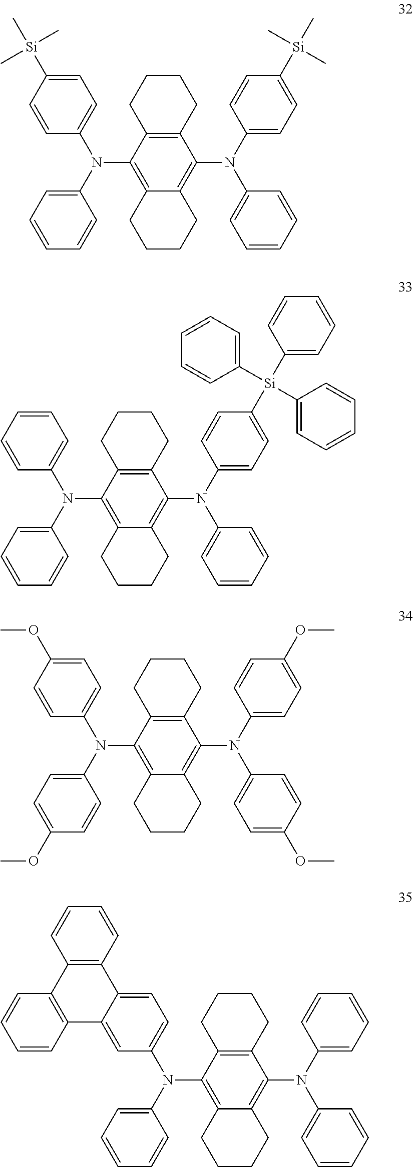

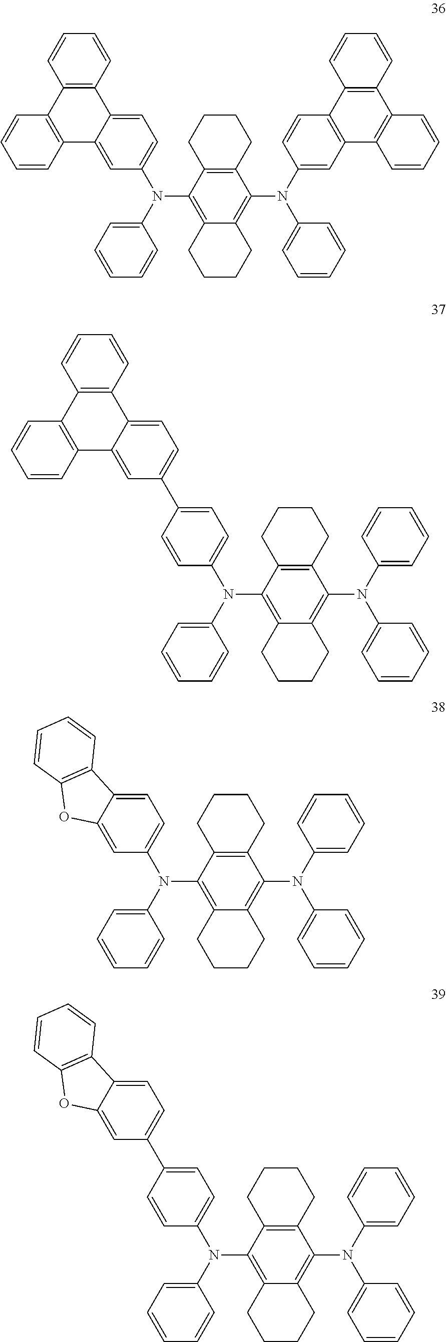 [SMILES: c1ccc(N(c2ccc3c4ccccc4c4ccccc4c3c2)c2c3c(c(N(c4ccccc4)c4ccc5c6ccccc6c6ccccc6c5c4)c4c2CCCC4)CCCC3)cc1 ; c1ccc(N(c2ccccc2)c2c3c(c(N(c4ccccc4)c4ccc(-c5ccc6c7ccccc7c7ccccc7c6c5)cc4)c4c2CCCC4)CCCC3)cc1 ; c1ccc(N(c2ccccc2)c2c3c(c(N(c4ccccc4)c4ccc5c(c4)oc4ccccc45)c4c2CCCC4)CCCC3)cc1 ; c1ccc(N(c2ccccc2)c2c3c(c(N(c4ccccc4)c4ccc(-c5ccc6c(c5)oc5ccccc56)cc4)c4c2CCCC4)CCCC3)cc1]

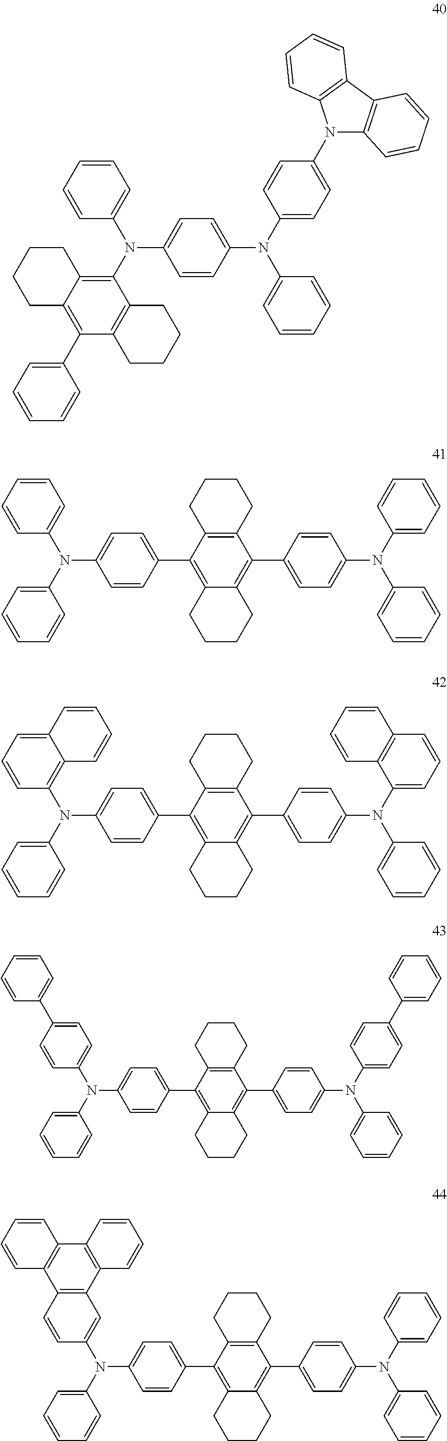

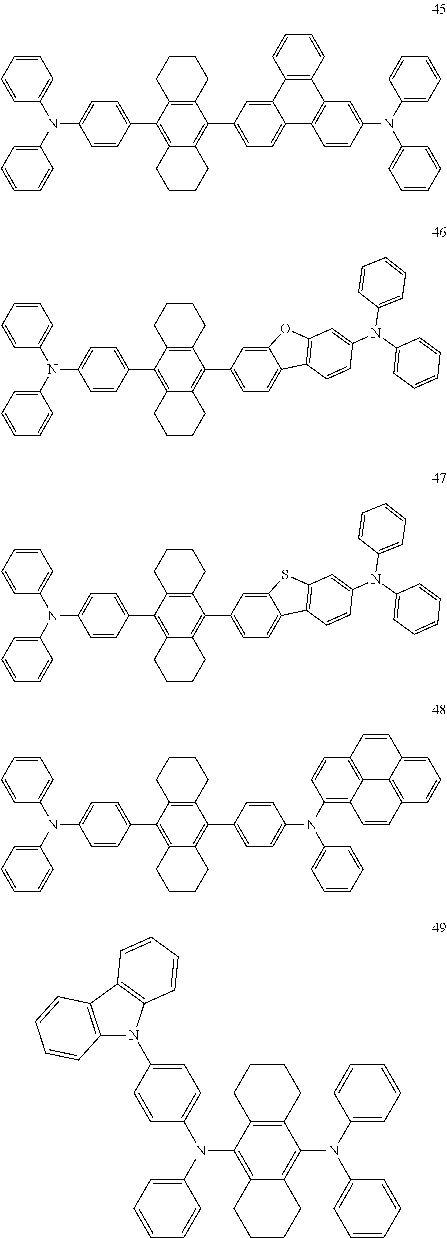

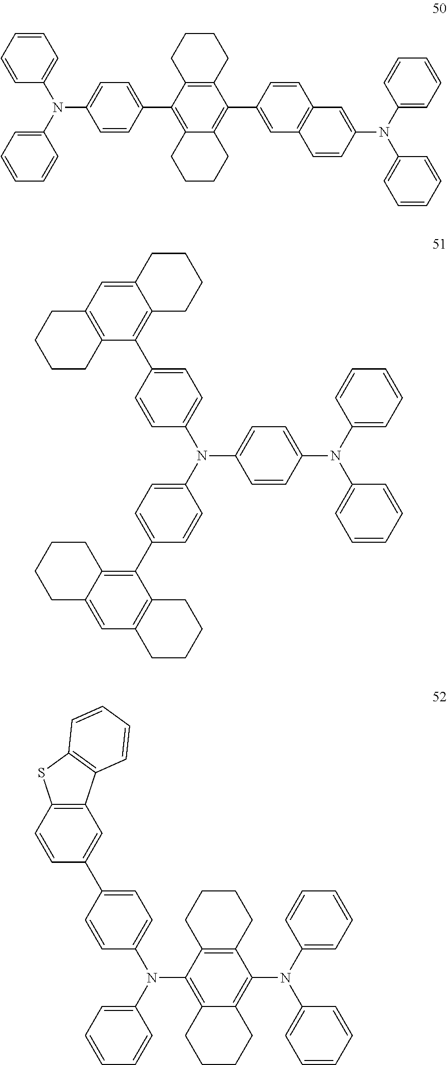 [SMILES: c1ccc(N(c2ccccc2)c2ccc(-c3c4c(c(-c5ccc6cc(N(c7ccccc7)c7ccccc7)ccc6c5)c5c3CCCC5)CCCC4)cc2)cc1 ; c1ccc(N(c2ccccc2)c2ccc(N(c3ccc(-c4c5c(cc6c4CCCC6)CCCC5)cc3)c3ccc(-c4c5c(cc6c4CCCC6)CCCC5)cc3)cc2)cc1 ; c1ccc(N(c2ccccc2)c2c3c(c(N(c4ccccc4)c4ccc(-c5ccc6sc7ccccc7c6c5)cc4)c4c2CCCC4)CCCC3)cc1]

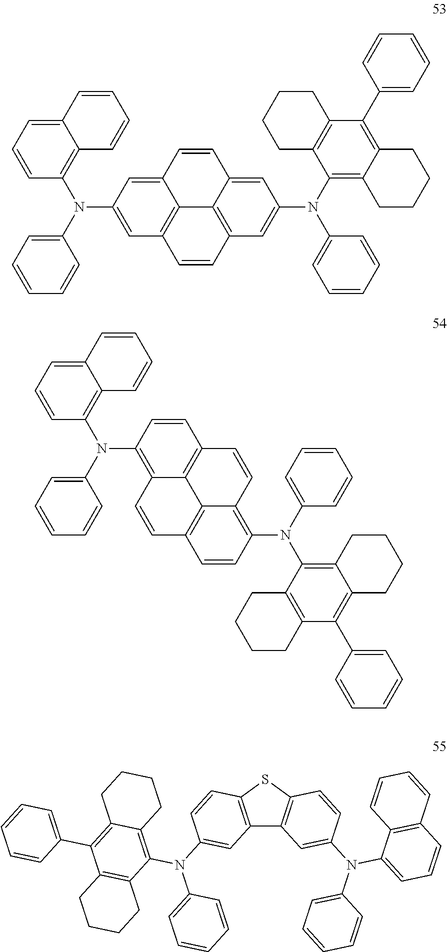 [SMILES: c1ccc(-c2c3c(c(N(c4ccccc4)c4cc5ccc6cc(N(c7ccccc7)c7cccc8ccccc78)cc7ccc(c4)c5c67)c4c2CCCC4)CCCC3)cc1 ; c1ccc(-c2c3c(c(N(c4ccccc4)c4ccc5ccc6c(N(c7ccccc7)c7cccc8ccccc78)ccc7ccc4c5c76)c4c2CCCC4)CCCC3)cc1 ; c1ccc(-c2c3c(c(N(c4ccccc4)c4ccc5sc6ccc(N(c7ccccc7)c7cccc8ccccc78)cc6c5c4)c4c2CCCC4)CCCC3)cc1]

A material for an organic EL device may include the diamine derivative.

The material for an organic EL device may be a hole transport material.

Embodiments are also directed to an organic EL device including the diamine derivative in a layer of stacked layers disposed between an emission layer and an anode to solve the above-described defects.

### BRIEF DESCRIPTION OF THE DRAWINGS

Features will become apparent to those of skill in the art by describing in detail exemplary embodiments with reference to the attached drawings in which:

FIG. 1 illustrates a schematic cross-sectional view depicting an organic EL device according to an embodiment; and

FIG. 2 illustrates a schematic diagram of an organic EL device manufactured by using an organic EL material according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “between” two layers, it can be the only layer between the two layers, or one or more intervening layers may also be present. Like reference numerals refer to like elements throughout.

(With Respect to Diamine Derivative)

First, diamine derivatives according to an embodiment will be explained in detail.

After examining the above-described tasks, the inventors of the present application found that a diamine derivative containing an octahydroanthracene group may be used as a material for a hole transport layer in an organic EL device and confirmed the improvement of the emission efficiency and the realization of the long life of the organic EL device. Hereinafter, the diamine derivative having the octahydroanthracene group will be explained.

The material for an organic EL device according to an embodiment may be an amine compound containing an octahydroanthracene group, represented by the following Formula (1).

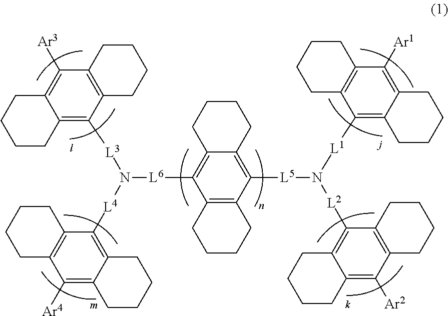

In the above Formula (1), Ar¹ to Ar⁴ are hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group, j, k, l, m and n are independently 0 or 1, where the relation of j+k+l+m+n≧1 is satisfied, and L¹ to L⁶ are independently a single bond, a substituted or unsubstituted aryl group or a substituted or unsubstituted heteroaryl group.

The diamine derivative containing the octahydroanthracene group may be a diamine derivative represented by the following Formula (2).

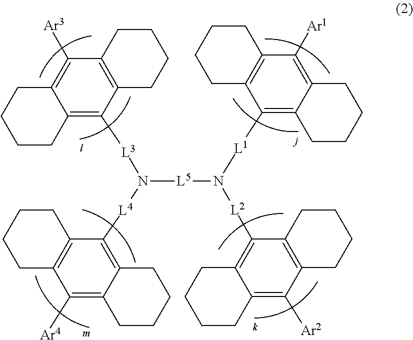

In the above Formula (2), Ar¹ to Ar⁴ are hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group, j, k, l and m are independently 0 or 1, where the relation of j+k+l+m≧1 is satisfied, and L¹ to L⁵ are independently a single bond, a substituted or unsubstituted aryl group or a substituted or unsubstituted heteroaryl group. (Formula (2) may be obtained from Formula (1) where, in Formula (1), n=0 and L⁶ is a single bond.)

The diamine derivative containing the octahydroanthracene group may be a diamine derivative represented by the following Formula (3).

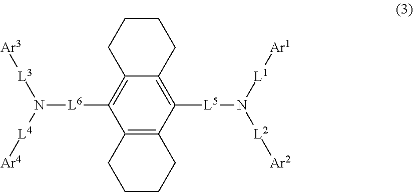

In the above Formula (3), Ar¹ to Ar⁴ are hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group, and L¹ to L⁶ are independently a single bond, a substituted or unsubstituted aryl group or a substituted or unsubstituted heteroaryl group. (Formula (3) may be obtained from Formula (1) where, in Formula (1), n=1 and j=k=l=m=0.)

In the above Formulae (1) to (3), Ar¹ to Ar⁴ may be, for example, a substituted or unsubstituted aryl group having 6 to 18 carbon atoms, a substituted or unsubstituted carbazolyl group, a substituted or unsubstituted benzofuryl group or a substituted or unsubstituted dibenzothienyl group. L¹ to L⁶ in the above Formulae (1) to (3) may independently be, for example, a single bond or a substituted or unsubstituted aryl group having 6 to 12 carbon atoms. In the above Formula (2), L¹ to L⁵ may independently be a single bond or a substituted or unsubstituted aryl group having 6 to 12 carbon atoms.

The alkyl group of the “substituted or unsubstituted alkyl group” in the above Formulae (1) to (3) may be one of a straight chain, a branched chain and a cyclic alkyl group. Examples of the alkyl group may include, for example, a methyl group, an ethyl group, a n-propyl group, an isopropyl group, a n-butyl group, an s-butyl group, a t-butyl group, a n-pentyl group, a neopentyl group, a n-hexyl group, a 2-ethylhexyl group, a n-heptyl group, a n-octyl group, a 2-hexyloctyl group, a n-nonyl group, a n-decyl group, a 2-hexyldecyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group, a n-icosyl group, a n-henicosyl group, a n-docosyl group, a n-tricosyl group, a n-tetracosyl group, a n-pentacosyl group, a n-hexacosyl group, a n-heptacosyl group, a n-octacosyl group, a n-nonacosyl group, a n-triacontyl group, a cyclopentyl group, a cyclohexyl group, a cycloheptyl group, etc. For example, the alkyl group may be a methyl group, an ethyl group, a n-propyl group, an isopropyl group, a n-butyl group, a s-butyl group, a t-butyl group, an-pentyl group, a neopentyl group, a n-hexyl group, a 2-ethylhexyl group, a n-heptyl group, a n-octyl group, a n-nonyl group, a n-decyl group, a 2-hexyldecyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group or a n-icosyl group. For example, the alkyl group may be a methyl group, an ethyl group, a n-propyl group, a n-butyl group, thae n-pentyl group, a n-hexyl group, a cyclohexyl group, a 2-ethylhexyl group, a n-heptyl group, a n-octyl group, a n-nonyl group, a n-decyl group, a n-undecyl group, a n-dodecyl group, a n-tridecyl group, a 2-hexyloctyl group, a n-tetradecyl group, a n-pentadecyl group, a n-hexadecyl group or a cycloheptyl group, etc.

In addition, the alkoxy group of the “substituted or unsubstituted alkoxy group” in the above Formulae (1) to (3) may be, for example, a methoxy group, an ethoxy group, a n-propoxy group, a n-butoxy group, a n-pentyloxy group, a n-hexyloxy group, a n-heptyloxy group, a n-octyloxy group, a n-nonyloxy group, a n-decyloxy group, a n-undecyloxy group, a n-dodecyloxy group, a n-tridecyloxy group, a n-tetradecyloxy group, a n-pentadecyloxy group, a n-hexadecyloxy group, a n-heptadecyloxy group, a n-octadecyloxy group, a n-nonadecyloxy group, a n-icosyloxy group, a n-henicosyloxy group, a n-docosyloxy group, a n-tricosyloxy group, a n-tetracosyloxy group, a n-pentacosyloxy group, a n-hexacosyloxy group, a n-heptacosyloxy group, a n-octacosyloxy group, a n-nonacosyloxy group, a n-triacontyloxy group, etc., without limitation. For example, the alkoxy group may be a methoxy group, an ethoxy group, a n-propoxy group, a n-butoxy group, a n-pentyloxy group, a n-hexyloxy group, a n-heptyloxy group, a n-octyloxy group, a n-nonyloxy group, a n-decyloxy group, a n-undecyloxy group, a n-dodecyloxy group, an-tridecyloxy group, a n-tetradecyloxy group, a n-pentadecyloxy group, a n-hexadecyloxy group, a n-heptadecyloxy group, the n-octadecyloxy group, the n-nonadecyloxy group, the n-icosyloxy group, etc., may be illustrated.

The aryl or heteroaryl group of the “substituted or unsubstituted aryl group” or the “substituted or unsubstituted heteroaryl group” in the above Formulae (1) to (3) may include, for example, a phenyl group, a naphthyl group, an anthracenyl group, a phenanthryl group, a biphenyl group, a terphenyl group, a fluorenyl group, a triphenylenyl group, a biphenylenyl group, a pyrenyl group, a benzothiazolyl group, a thiophenyl group, a thienothiophenyl group, a thienothienothiophenyl group, a benzothiophenyl group, a dibenzothiophenyl group, a benzofuryl group, a N-arylcarbazolyl group, a N-heteroarylcarbazolyl group, a N-alkylcarbazolyl group, a phenoxazyl group, a phenothiazyl group, a pyridyl group, a pyrimidyl group, a triazinyl group, a quinolinyl group, a quinoxalyl group, etc.

For example, in the above Formulae (1) to (3), the aryl or heteroaryl group of Ar¹ to Ar⁴ may be a phenyl group, a naphthyl group, a biphenyl group, a terphenyl group, a fluorenyl group, a triphenylenyl group, a pyrenyl group, a dibenzothiophenyl group, a benzofuryl group or a N-phenylcarbazolyl group. For example, the aryl group or heteroaryl group may be a phenyl group, a naphthyl group, a biphenyl group, a fluorenyl group, a triphenylenyl group, a dibenzothiophenyl group, a benzofuryl group or a N-phenylcarbazolyl group.

The “triarylsilyl group” of the “substituted or unsubstituted triarylsilyl group” in the above Formulae (1) to (3) may be a three-substituted silyl group in which three aryl groups are combined with a silicon atom. The aryl group combined with the silicon atom may be one of the above-described aryl groups. For example, the “triarylsilyl group” may be a triphenylsilyl group, a tri(2-methylphenyl)silyl group, a tri(3-methylphenyl)silyl group, a tri(4-methylphenyl)silyl group, a tri(2,6-dimethylphenyl)silyl group, a tri(3,5-dimethylphenyl)silyl group, a tri(2,4,6-trimethylphenyl)silyl group, etc.

In addition, the “trialkylsilyl group” of the “substituted or unsubstituted trialkylsilyl group” in the above Formulae (1) to (3) may be a three-substituted silyl group in which three alkyl groups are combined with a silicon atom. The alkyl group combined with the silicon atom may be one of the above-described alkyl groups. For example, the “trialkylsilyl group” may be a trimethylsilyl group, a triethylsilyl group, a tri-n-propylsilyl group, a triisopropylsilyl group, a tri-n-butylsilyl group, a tri-s-butylsilyl group, a tri-t-butylsilyl group, a tri-isobutylsilyl group, a t-butyl-dimethylsilyl group, a tri-n-pentylsilyl group, a tri-n-hexylsilyl group, a dimethyl-n-dodecylsilyl group, etc. For example, the trialkylsilyl group may be a trimethylsilyl group, a tri-n-propylsilyl group, a tri-n-butylsilyl group, a tri-n-pentylsilyl group, a tri-n-hexylsilyl group, etc.

In the diamine derivative represented by the above Formulae (1) and (3), substituents L¹ to L⁶ combined with a nitrogen atom, and substituents Ar¹ to Ar⁴ introduced in the octahydroanthracene group may have the relations of one of the following (a) to (d).

(a) Ar¹=Ar³, Ar²=Ar⁴, L¹=L³ and L²=L⁴

(b) Ar¹=Ar², Ar³=Ar⁴, L¹=L² and L³=L⁴

(c) Ar¹=Ar²=Ar³=Ar⁴, and L¹=L₂=L³=L⁴

(d) L⁵=L⁶

In the diamine derivative represented by the above Formulae (2), substituents L¹ to L⁵ combined with a nitrogen atom, and substituents Ar¹ to Ar⁴ introduced in the octahydroanthracene group may have the relations of the following (a) to (c).

(a) Ar¹=Ar³, Ar²=Ar⁴, L¹=L³ and L²=L⁴

(b) Ar¹=Ar², Ar³=Ar⁴, L¹=L² and L³=L⁴

(c) Ar¹=Ar²=Ar³=Ar⁴, and L¹=L²=L³=L⁴

In the case that the relation of the above (a), (b), (c) or (d) is satisfied, the molecular symmetry of the diamine derivative represented by the above Formulae (1) to (3) may be increased, and the synthesis of a corresponding amine derivative may be easier.

The parameters j, k, l and m representing the number of the octahydroanthracene group present in the molecule may have the relation of the following (e) or (f).

(e) j=l and k=m

(f) j=k and l=m

In the case that the relation of the above (e) or (f) is satisfied, bilaterally symmetrical or vertically symmetrical octahydroanthracene groups may be introduced in the diamine derivative represented by the above Formula (1) or (2).

For example, diamine derivative may satisfy the relation of the above (a), (b), (c) or (d) and the relation of the above (e) or (f).

For example, the diamine derivative containing the octahydroanthracene group represented by the above Formula (1) may include at least one compound represented by the following structures.

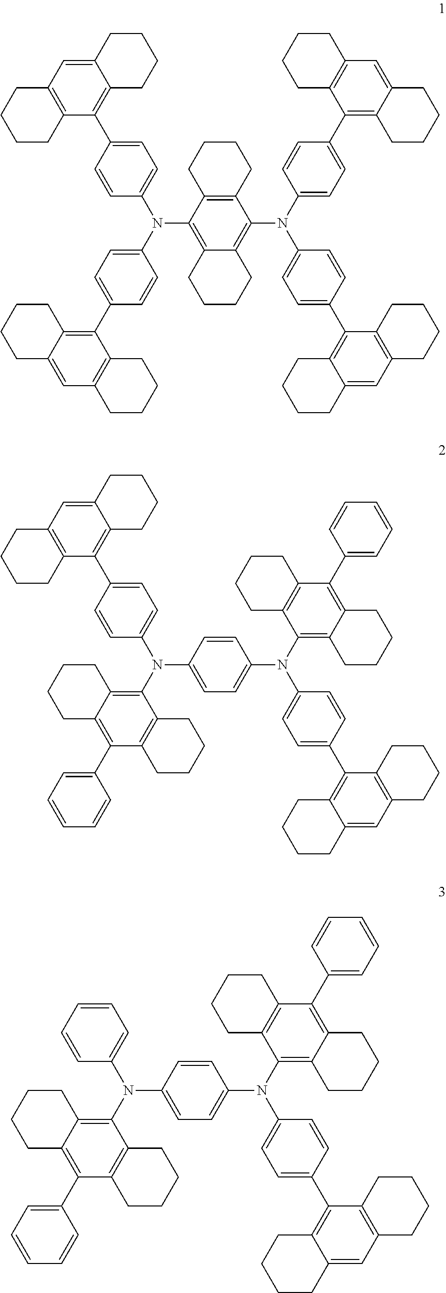 [SMILES: c1cc(N(c2ccc(-c3c4c(cc5c3CCCC5)CCCC4)cc2)c2c3c(c(N(c4ccc(-c5c6c(cc7c5CCCC7)CCCC6)cc4)c4ccc(-c5c6c(cc7c5CCCC7)CCCC6)cc4)c4c2CCCC4)CCCC3)ccc1-c1c2c(cc3c1CCCC3)CCCC2 ; c1ccc(-c2c3c(c(N(c4ccc(-c5c6c(cc7c5CCCC7)CCCC6)cc4)c4ccc(N(c5ccc(-c6c7c(cc8c6CCCC8)CCCC7)cc5)c5c6c(c(-c7ccccc7)c7c5CCCC7)CCCC6)cc4)c4c2CCCC4)CCCC3)cc1 ; c1ccc(-c2c3c(c(N(c4ccccc4)c4ccc(N(c5ccc(-c6c7c(cc8c6CCCC8)CCCC7)cc5)c5c6c(c(-c7ccccc7)c7c5CCCC7)CCCC6)cc4)c4c2CCCC4)CCCC3)cc1]

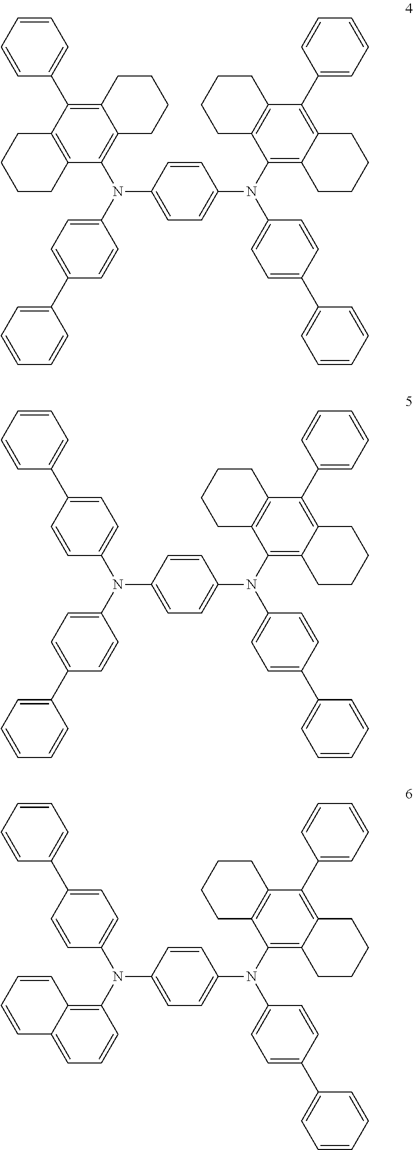

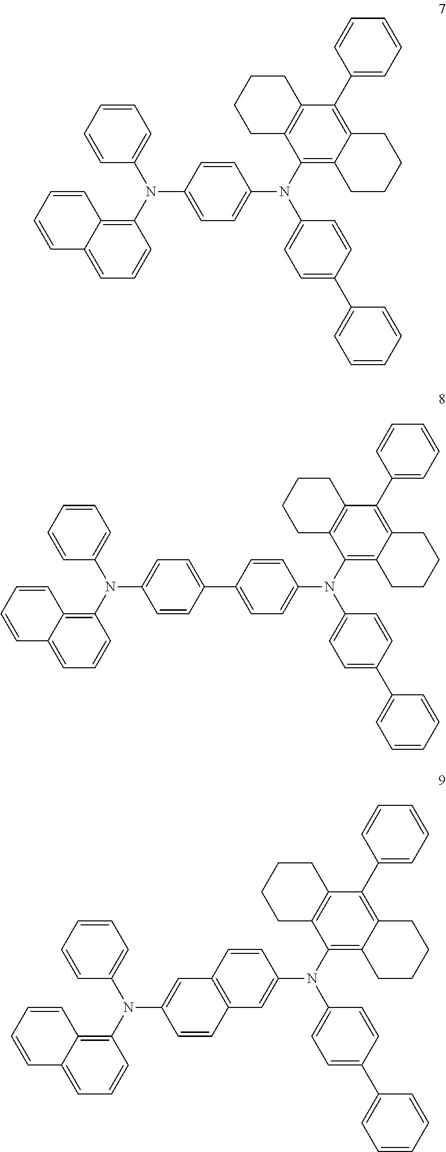 [SMILES: c1ccc(-c2ccc(N(c3ccc(N(c4ccccc4)c4cccc5ccccc45)cc3)c3c4c(c(-c5ccccc5)c5c3CCCC5)CCCC4)cc2)cc1 ; c1ccc(-c2ccc(N(c3ccc(-c4ccc(N(c5ccccc5)c5cccc6ccccc56)cc4)cc3)c3c4c(c(-c5ccccc5)c5c3CCCC5)CCCC4)cc2)cc1 ; c1ccc(-c2ccc(N(c3ccc4cc(N(c5ccccc5)c5cccc6ccccc56)ccc4c3)c3c4c(c(-c5ccccc5)c5c3CCCC5)CCCC4)cc2)cc1]

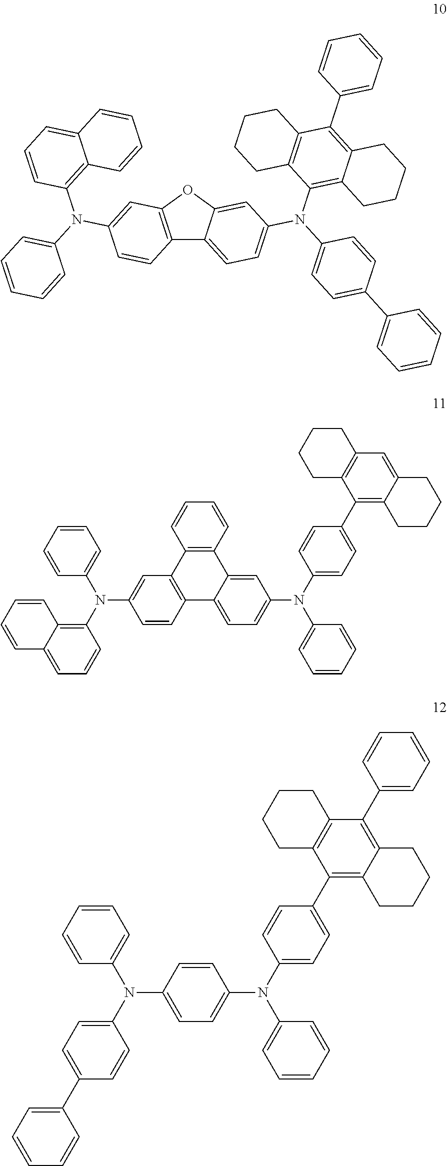 [SMILES: c1ccc(-c2ccc(N(c3ccc4c(c3)oc3cc(N(c5ccccc5)c5cccc6ccccc56)ccc34)c3c4c(c(-c5ccccc5)c5c3CCCC5)CCCC4)cc2)cc1 ; c1ccc(N(c2ccc(-c3c4c(cc5c3CCCC5)CCCC4)cc2)c2ccc3c4ccc(N(c5ccccc5)c5cccc6ccccc56)cc4c4ccccc4c3c2)cc1 ; c1ccc(-c2ccc(N(c3ccccc3)c3ccc(N(c4ccccc4)c4ccc(-c5c6c(c(-c7ccccc7)c7c5CCCC7)CCCC6)cc4)cc3)cc2)cc1]

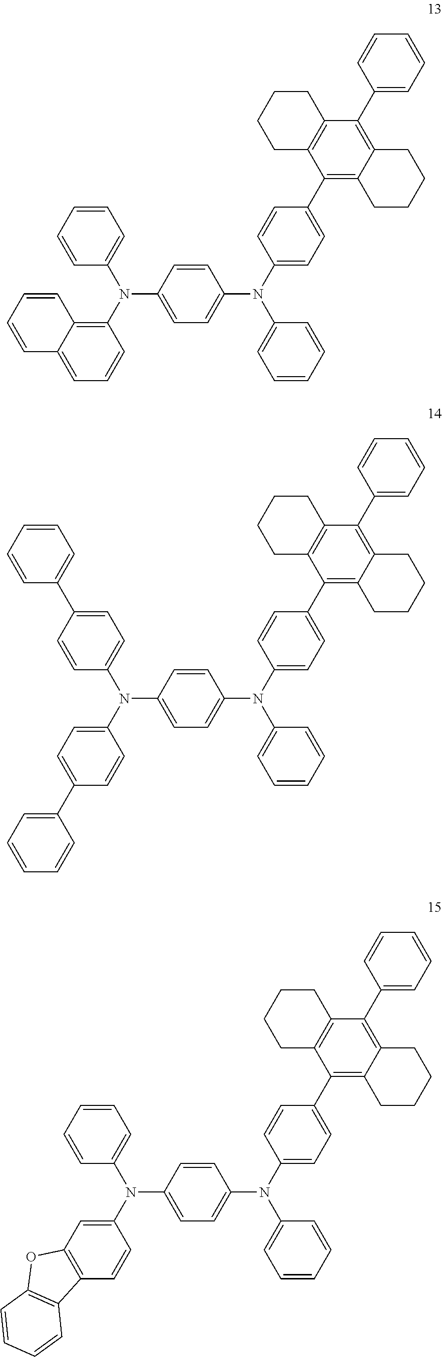 [SMILES: c1ccc(-c2c3c(c(-c4ccc(N(c5ccccc5)c5ccc(N(c6ccccc6)c6cccc7ccccc67)cc5)cc4)c4c2CCCC4)CCCC3)cc1 ; c1ccc(-c2ccc(N(c3ccc(-c4ccccc4)cc3)c3ccc(N(c4ccccc4)c4ccc(-c5c6c(c(-c7ccccc7)c7c5CCCC7)CCCC6)cc4)cc3)cc2)cc1 ; c1ccc(-c2c3c(c(-c4ccc(N(c5ccccc5)c5ccc(N(c6ccccc6)c6ccc7c(c6)oc6ccccc67)cc5)cc4)c4c2CCCC4)CCCC3)cc1]

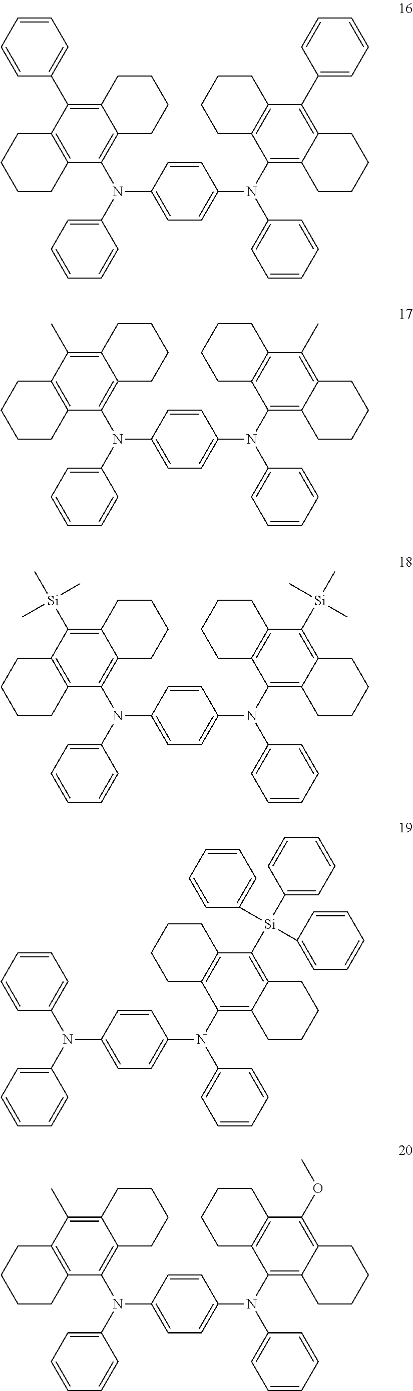

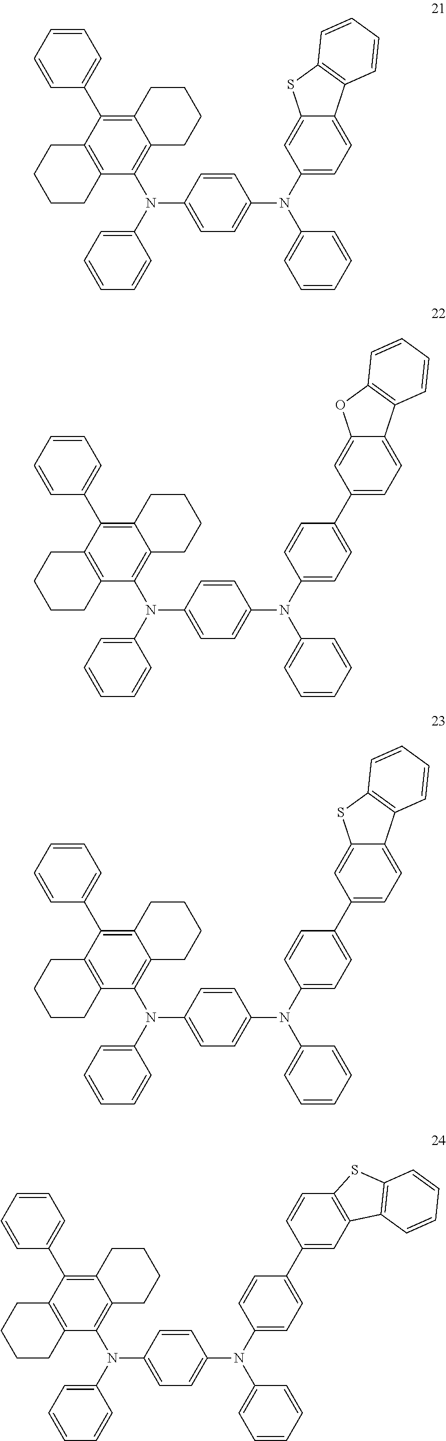 [SMILES: c1ccc(-c2c3c(c(N(c4ccccc4)c4ccc(N(c5ccccc5)c5ccc6c(c5)sc5ccccc56)cc4)c4c2CCCC4)CCCC3)cc1 ; c1ccc(-c2c3c(c(N(c4ccccc4)c4ccc(N(c5ccccc5)c5ccc(-c6ccc7c(c6)oc6ccccc67)cc5)cc4)c4c2CCCC4)CCCC3)cc1 ; c1ccc(-c2c3c(c(N(c4ccccc4)c4ccc(N(c5ccccc5)c5ccc(-c6ccc7c(c6)sc6ccccc67)cc5)cc4)c4c2CCCC4)CCCC3)cc1 ; c1ccc(-c2c3c(c(N(c4ccccc4)c4ccc(N(c5ccccc5)c5ccc(-c6ccc7sc8ccccc8c7c6)cc5)cc4)c4c2CCCC4)CCCC3)cc1]

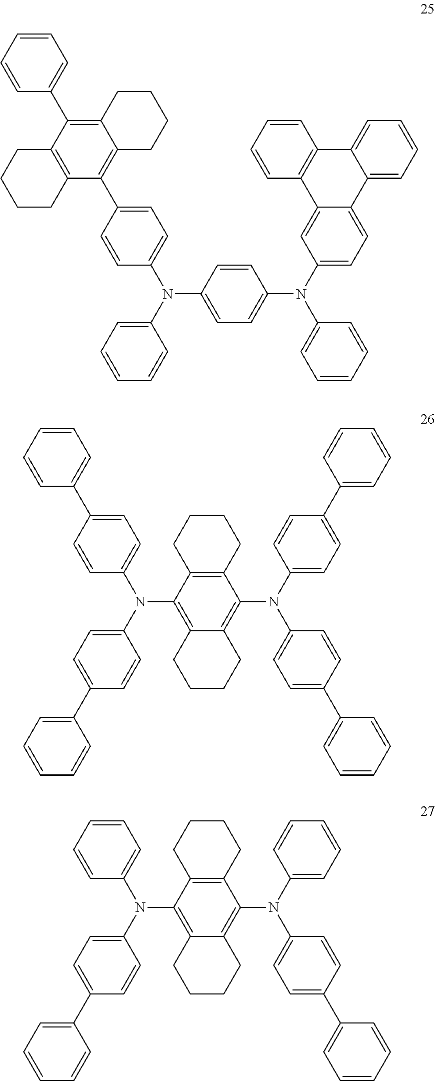 [SMILES: c1ccc(-c2c3c(c(-c4ccc(N(c5ccccc5)c5ccc(N(c6ccccc6)c6ccc7c8ccccc8c8ccccc8c7c6)cc5)cc4)c4c2CCCC4)CCCC3)cc1 ; c1ccc(-c2ccc(N(c3ccc(-c4ccccc4)cc3)c3c4c(c(N(c5ccc(-c6ccccc6)cc5)c5ccc(-c6ccccc6)cc5)c5c3CCCC5)CCCC4)cc2)cc1 ; c1ccc(-c2ccc(N(c3ccccc3)c3c4c(c(N(c5ccccc5)c5ccc(-c6ccccc6)cc5)c5c3CCCC5)CCCC4)cc2)cc1]

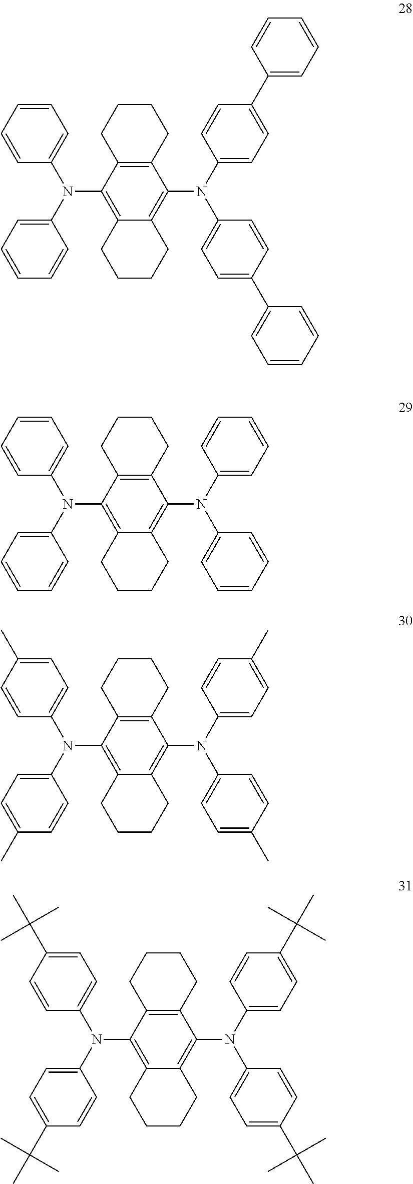

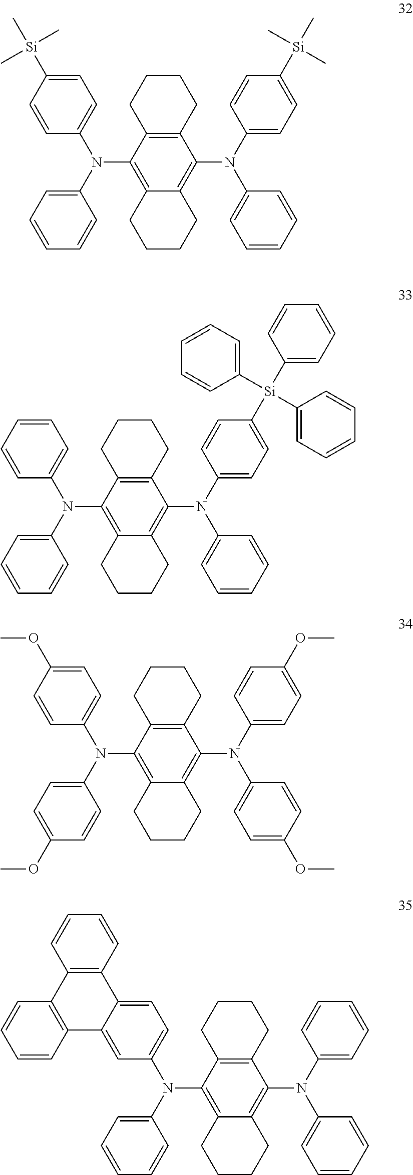

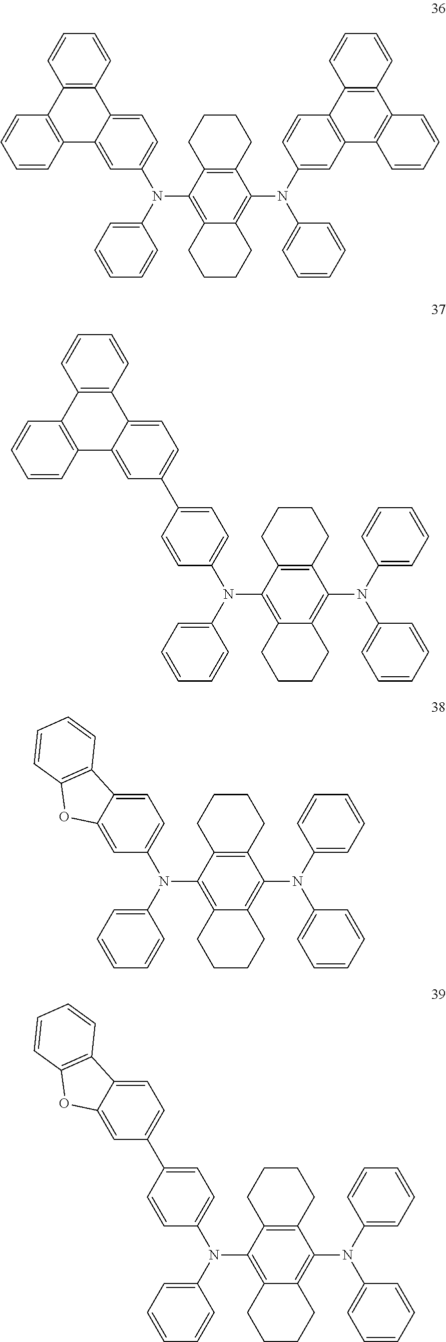 [SMILES: c1ccc(N(c2ccc3c4ccccc4c4ccccc4c3c2)c2c3c(c(N(c4ccccc4)c4ccc5c6ccccc6c6ccccc6c5c4)c4c2CCCC4)CCCC3)cc1 ; c1ccc(N(c2ccccc2)c2c3c(c(N(c4ccccc4)c4ccc(-c5ccc6c7ccccc7c7ccccc7c6c5)cc4)c4c2CCCC4)CCCC3)cc1 ; c1ccc(N(c2ccccc2)c2c3c(c(N(c4ccccc4)c4ccc5c(c4)oc4ccccc45)c4c2CCCC4)CCCC3)cc1 ; c1ccc(N(c2ccccc2)c2c3c(c(N(c4ccccc4)c4ccc(-c5ccc6c(c5)oc5ccccc56)cc4)c4c2CCCC4)CCCC3)cc1]

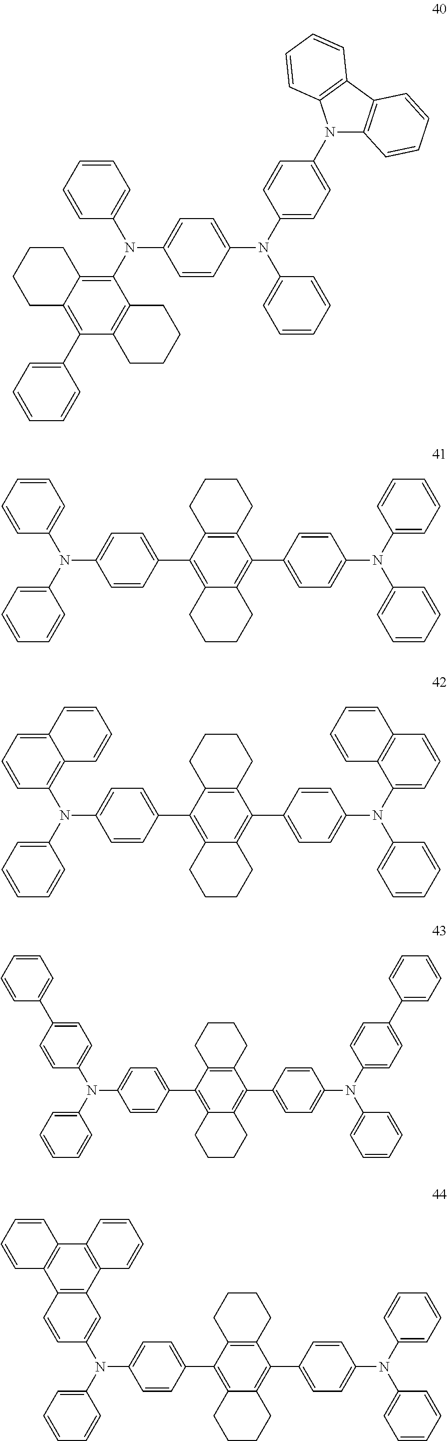

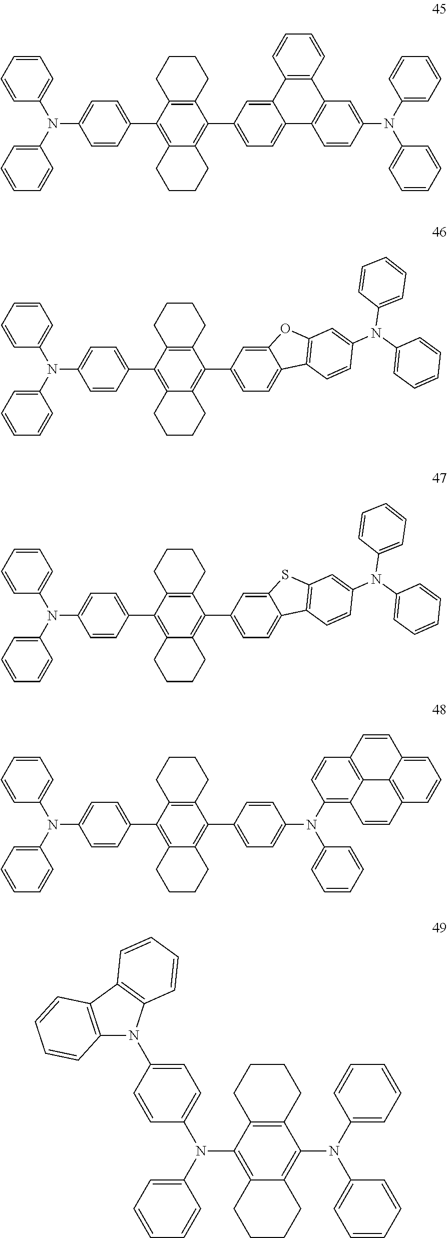

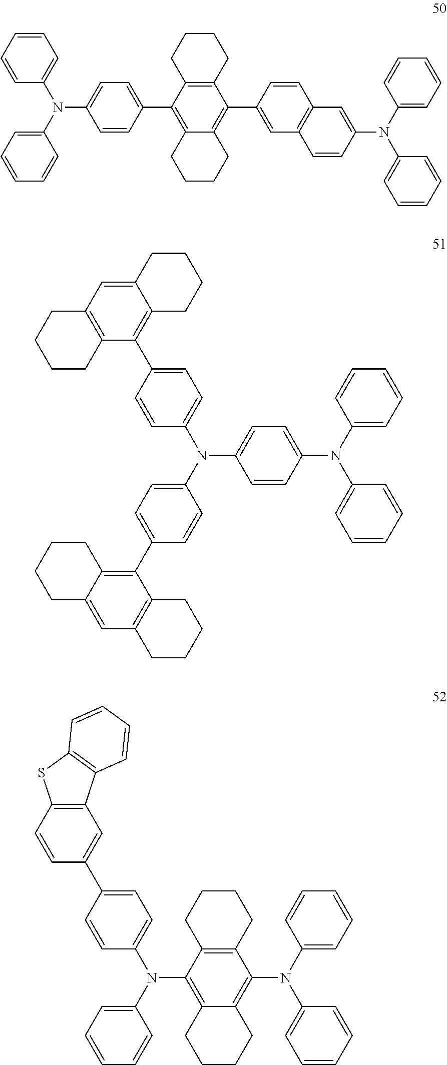 [SMILES: c1ccc(N(c2ccccc2)c2ccc(-c3c4c(c(-c5ccc6cc(N(c7ccccc7)c7ccccc7)ccc6c5)c5c3CCCC5)CCCC4)cc2)cc1 ; c1ccc(N(c2ccccc2)c2ccc(N(c3ccc(-c4c5c(cc6c4CCCC6)CCCC5)cc3)c3ccc(-c4c5c(cc6c4CCCC6)CCCC5)cc3)cc2)cc1 ; c1ccc(N(c2ccccc2)c2c3c(c(N(c4ccccc4)c4ccc(-c5ccc6sc7ccccc7c6c5)cc4)c4c2CCCC4)CCCC3)cc1]

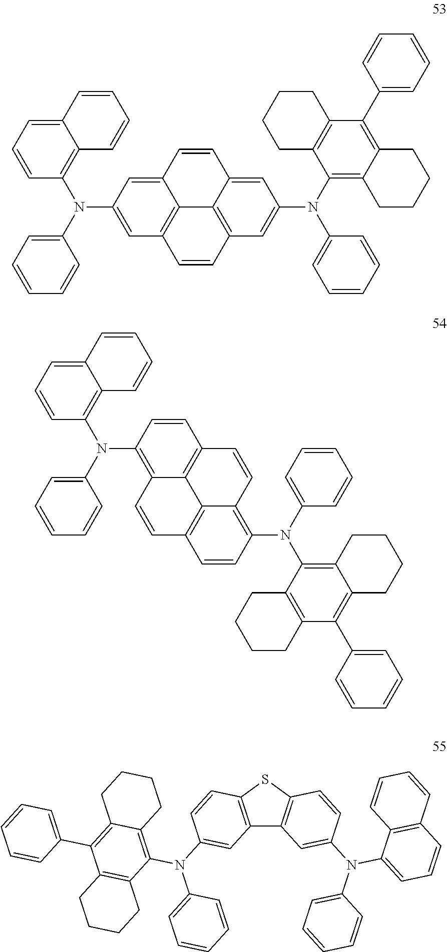 [SMILES: c1ccc(-c2c3c(c(N(c4ccccc4)c4cc5ccc6cc(N(c7ccccc7)c7cccc8ccccc78)cc7ccc(c4)c5c67)c4c2CCCC4)CCCC3)cc1 ; c1ccc(-c2c3c(c(N(c4ccccc4)c4ccc5ccc6c(N(c7ccccc7)c7cccc8ccccc78)ccc7ccc4c5c76)c4c2CCCC4)CCCC3)cc1 ; c1ccc(-c2c3c(c(N(c4ccccc4)c4ccc5sc6ccc(N(c7ccccc7)c7cccc8ccccc78)cc6c5c4)c4c2CCCC4)CCCC3)cc1]

One or more of the diamine derivatives described above may be used as the material for an organic EL device. The diamine derivative represented by Formulae (1) to (3) may include at least one octahydroanthracene group in the molecular structure thereof. Thus, the diamine derivative according to embodiments may be stable with respect to electrons, and may be used as a material for an organic EL device, particularly, as a material for a hole transport layer adjacent to an emission layer. By using the diamine derivative according to embodiments as the material of the hole transport layer, the electron tolerance of the hole transport layer may be improved, the deterioration of a hole transport material due to electrons breaking into the hole transport layer may be restrained, and the long life of the organic EL device may be realized. In addition, by using the diamine derivative according to embodiments as the hole transport material, the emission efficiency of the organic EL device in a blue emission region and a green emission region may be improved further.

In other implementations, the diamine derivative according to embodiments may be used as a material of a hole injection layer. In the case that the diamine derivative according to embodiments is used as the material of the hole injection layer, the deterioration of the hole injection layer due to electrons may be restrained, and a long life of the organic EL device may be realized as in the case of being used as the material of the hole transport layer. In addition, since the diamine derivative according to embodiments has electron tolerance, the diamine derivative may be used as a host material of an emission layer.

(With Respect to an Organic EL Device Using Diamine Derivative)

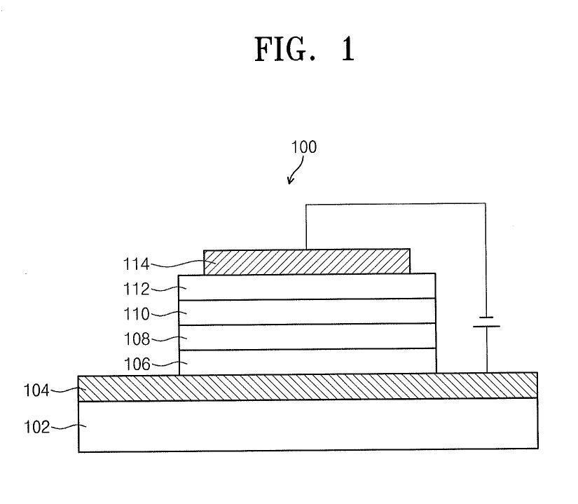

Hereinafter, referring to FIG. 1, an organic EL device using the diamine derivative according to embodiments will be described in brief. FIG. 1 illustrates a schematic cross-sectional view of an organic EL device according to an embodiment.

The organic EL device may have, for example, a structure illustrated in FIG. 1.

FIG. 1 is a schematic cross-sectional view of an organic EL device 100 using a diamine derivative as a material for the organic EL device. The organic EL device 100 may include, for example, a glass substrate 102, an anode 104 disposed on the glass substrate 102, a hole injection layer 106 disposed on the anode 104, a hole transport layer 108 disposed on the hole injection layer 106, an emission layer 110 disposed on the hole transport layer 108, an electron transport layer 112 disposed on the emission layer 110 and a cathode 114 disposed on the electron transport layer 112. The electron transport layer 112 may function as an electron injection layer.

An embodiment using the material for an organic EL device in the hole transport layer 108 will be explained. The substrate 102 may be a transparent glass substrate, a semiconductor substrate formed by using silicon, etc., or a flexible substrate of a resin, etc. The anode 104 may be disposed on the substrate 102. The anode 104 may be formed using indium tin oxide (ITO), indium zinc oxide (IZO), etc. The hole injection layer 106 may be disposed on the anode 104. The hole injection layer 106 may include, for example, 4,4′,4″-tris[2-naphthyl)(phenyl)amino]triphenylamine (2-TNATA), N,N,N′,N′-tetrakis(3-methylphenyl)-3,3′-dimethylbenzidine (HMTPD), dipyrazino[2,3-f:2′,3′-h]quinoxaline-2,3,6,7,10,11-hexacarbonitrile (HAT(CN)₆), etc. The hole transport layer 108 may be disposed on the hole injection layer 106. The hole injection layer 106 may be formed using the material for an organic EL device. The emission layer 110 may be disposed on the hole transport layer 108. The emission layer 110 may be formed using, for example, a host material including 9,10-di(2-naphthyl)anthracene (ADN) doped with 2,5,8,11-tetra-t-butylperylene (TBP). The electron transport layer 112 may be disposed on the emission layer 110. The electron transport layer 112 may be formed using, for example, a material including tris(8-hydroxyquinolinato)aluminum (Alq₃). The electron injection layer 114 may be disposed on the electron transport layer 112. The electron injection layer 114 may be formed using, for example, a material including lithium fluoride (LiF). The cathode 116 may be disposed on the electron injection layer 114. The cathode 116 may be formed using a metal such as Al or a transparent material such as ITO, IZO, etc. The above-described thin layers may be formed by selecting an appropriate layer forming method such as vacuum deposition, sputtering, various coatings, etc.

In the organic EL device 100, an organic EL device driven at a low voltage and having high emission efficiency and long life may be manufactured by using the material for an organic EL device in a layer of stacked layers disposed between an anode and an emission layer, particularly in a hole transport layer. Particularly, remarkable effects may be obtained by using the material for an organic EL device in a blue emission region and a green emission region. In addition, the material for an organic EL device may be applied in an organic EL apparatus of an active matrix using thin film transistors (TFT).

By using the diamine derivative according to embodiments as at least one material of a hole injection material and a hole transport material of the hole injection layer 106 and the hole transport layer 108 of the organic EL device, a long life and high efficiency of the organic EL device may be realized.

In the structure of the organic EL device 100 shown in FIG. 1, suitable materials for an organic EL device may be used for the anode 104, the emission layer 110, the electron transport layer 112 and the cathode 114. As described above, the diamine derivative according to embodiments may be a compound that provides the high efficiency and the long life of the organic EL device in blue and green emission regions. Accordingly, emission materials capable of emitting blue and green emission may be used.

In addition, the diamine derivative according to embodiments may have electron tolerance as described above. Accordingly, the diamine derivative may be used as the hole transport material or the hole injection material of an organic EL device. In other implementations, the diamine derivative according to embodiments may be used as a host material in an emission layer.

As described above, an embodiment of the organic EL device using the diamine derivative according to embodiments has been explained in brief with reference to FIG. 1.

### EXAMPLES

Hereinafter, diamine derivatives and organic EL devices according to exemplary embodiments will be described in detail. In addition, the embodiments illustrated hereinafter are illustrated as embodiments, and the diamine derivatives and the organic EL devices according to exemplary embodiments are not limited to the following embodiments.

Hereinafter, particular embodiments on synthesizing Compounds 42, 16, 51 and 40 will be described in detail as the diamine derivatives according to an embodiment. Of course, the following synthetic methods are illustrated as embodiments, and the synthetic method of the diamine derivative is not limited to the following. To synthesize the material for an organic EL device, a suitable palladium catalyst, phosphine ligand, and alkaline (basic) reagent may be used. For example, bis(dibenzylideneacetone)palladium(0) may be used as the palladium catalyst, tri-tert-butyl phosphine may be used as the phosphine ligand, and sodium tert-butoxide may be used as the basic reagent.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

[Synthesis of Compound 42]

The following reaction is a synthetic process of Compound 42 as a diamine derivative according to an embodiment.

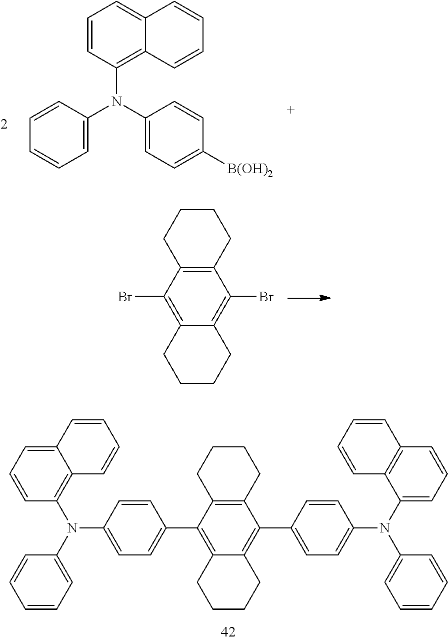

Compound 42 was synthesized by the following.

The boronic acid substituted amine compound represented above (8 mmol), the dibromohydroanthracene compound represented above (4 mmol), a palladium catalyst (0.4 mmol), a phosphine ligand (1.6 mmol), an basic reagent (16 mmol), toluene (250 mL), water (25 mL), and ethanol (13 mL) were added to a reaction vessel, followed by charging with nitrogen therein and refluxing while stirring for 25 hours. After cooling, water was poured into the reaction mixture, and an organic layer was extracted. The organic layer thus obtained was dried with magnesium sulfate anhydrous and filtered. The filtrate thus obtained was concentrated by a rotary evaporator, and the crude product thus obtained was separated by silica gel column chromatography. The solid thus obtained was recrystallized to produce Compound 42 as a target material with yield of 13% (APCI+: C₅₈H₄₈N₂, measured value 772).

[Synthesis of Compound 16]

The following reaction is a synthetic process of Compound 16 as a diamine derivative according to an embodiment.

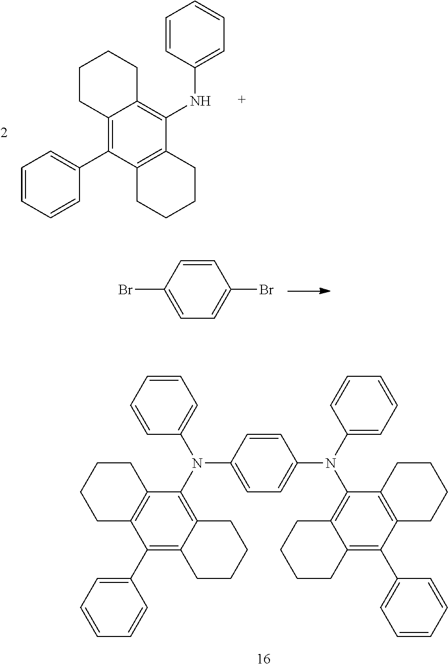

Compound 16 was synthesized by the following.

The amine compound represented above (4 mmol), p-dibromobenzene (2 mmol), a palladium catalyst (0.2 mmol), a phosphine ligand (0.8 mmol), an basic reagent (8 mmol) and toluene (200 mL) were added to a reaction vessel, followed by charging with nitrogen therein and refluxing while stirring for 15 hours. After cooling, water was poured into the reaction mixture, and an organic layer was extracted. The organic layer thus obtained was dried with magnesium sulfate anhydrous and filtered. The filtrate thus obtained was concentrated by a rotary evaporator, and the crude product thus obtained was separated by silica gel column chromatography. The solid thus obtained was recrystallized to produce Compound 16 as a target material with yield of 20% (APCI+: C₅₈H₅₆N₂, measured value 780).

[Synthesis of Compound 51]

The following reaction is a synthetic process of Compound 51 as a diamine derivative according to an embodiment.

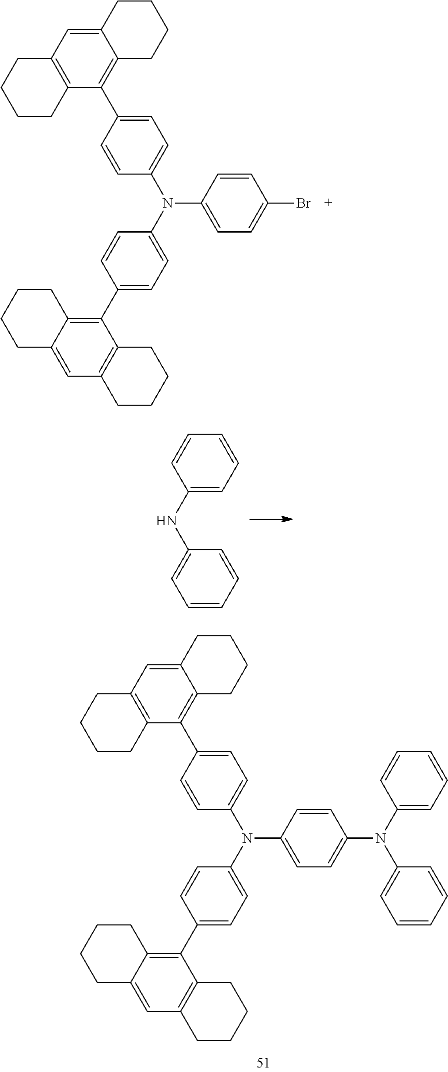

Compound 51 was synthesized by the following.

The bromine substituted amine compound represented above (5 mmol), diphenylamine (5 mmol), a palladium catalyst (0.5 mmol), a phosphine ligand (2.0 mmol), an basic reagent (20 mmol) and toluene (200 mL) were added to a reaction vessel, followed by charging with nitrogen therein and refluxing while stirring for 10 hours. After cooling, water was poured into the reaction mixture, and an organic layer was extracted. The organic layer thus obtained was dried with magnesium sulfate anhydrous and filtered. The filtrate thus obtained was concentrated by a rotary evaporator, and the crude product thus obtained was separated by silica gel column chromatography. The solid thus obtained was recrystallized to produce Compound 51 as a target material with yield of 60% (APCI+: C₅₈H₅₆N₂, measured value 780).

[Synthesis of Compound 40]

The following reaction is a synthetic process of Compound 40 as a diamine derivative according to an embodiment.

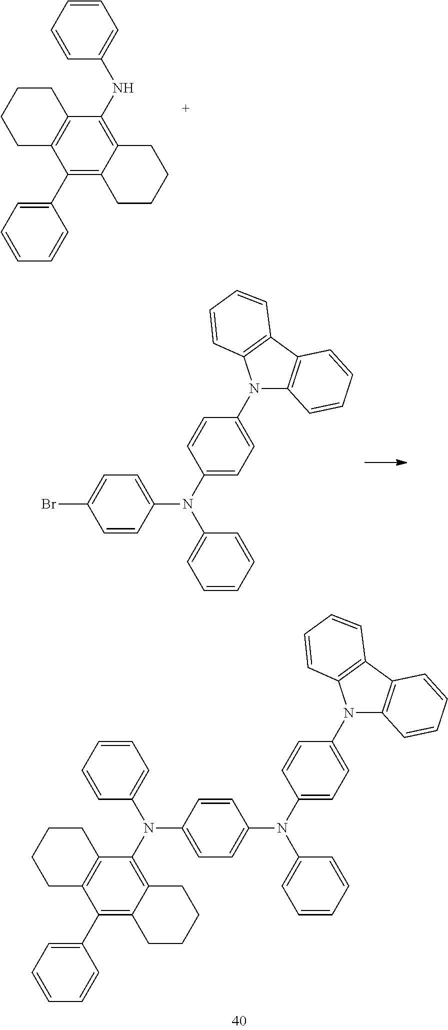 [SMILES: c1ccc(Nc2c3c(c(-c4ccccc4)c4c2CCCC4)CCCC3)cc1 ; Brc1ccc(N(c2ccccc2)c2ccc(-n3c4ccccc4c4ccccc43)cc2)cc1 ; c1ccc(-c2c3c(c(N(c4ccccc4)c4ccc(N(c5ccccc5)c5ccc(-n6c7ccccc7c7ccccc76)cc5)cc4)c4c2CCCC4)CCCC3)cc1]

Compound 40 was synthesized by the following.

The amine compound represented above (3 mmol), a bromine substituted amine compound represented above (3 mmol), a palladium catalyst (0.3 mmol), a phosphine ligand (1.2 mmol), an basic reagent (12 mmol) and toluene (220 mL) were added to a reaction vessel, followed by charging with nitrogen therein and refluxing while stirring for 18 hours. After cooling, water was poured into the reaction mixture, and an organic layer was extracted. The organic layer thus obtained was dried with magnesium sulfate anhydrous and filtered. The filtrate thus obtained was concentrated by a rotary evaporator, and the crude product thus obtained was separated by silica gel column chromatography. The solid thus obtained was recrystallized to produce Compound 40 as a target material with yield of 11% (APCI+:

C₅₆H₄₇N₃, measured value 761).

[Manufacture of Organic EL Device]

### Example 1

The manufacture of an organic EL device according to an embodiment was conducted by using a vacuum deposition method according to the following procedure. First, an ITO-glass substrate patterned and cleaned in advance was surface treated using ozone (O₃). The thickness of the ITO layer was about 150 nm. After ozone treatment, a layer was formed on the ITO layer using 2-TNATA as a hole injection material to a thickness of about 60 nm.

Then, a layer was formed using Compound 42 as a hole transport material to a thickness of about 30 nm to form a hole transport layer (HTL). Then, a layer was formed by co-depositing ADN doped with 3% of TBP to a thickness of about 25 nm.

Then, a layer was formed using Alq3 as an electron transport material to a thickness of about 25 nm, a layer was formed using lithium fluoride (LiF) as an electron injection material, and a cathode was formed using aluminum to a thickness of about 100 nm one by one to manufacture an organic EL device 200.

### Example 2

An organic EL device was manufactured by conducting the same procedure described in Example 1 except for using Compound 16 instead of Compound 42.

### Example 3

An organic EL device was manufactured by conducting the same procedure described in Example 1 except for using Compound 51 instead of Compound 42.

### Example 4

An organic EL device was manufactured by conducting the same procedure described in Example 1 except for using Compound 40 instead of Compound 42.

### Comparative Examples 1 and 2

Organic EL devices were manufactured by conducting the same procedure described in Example 1 except for using the following Comparative Compounds 1 and 2 as the materials for hole transport layers of organic EL devices. Here, the compounds used in Comparative Examples 1 and 2 are different from the diamine derivative according to an embodiment in not including an octahydroanthracene group.

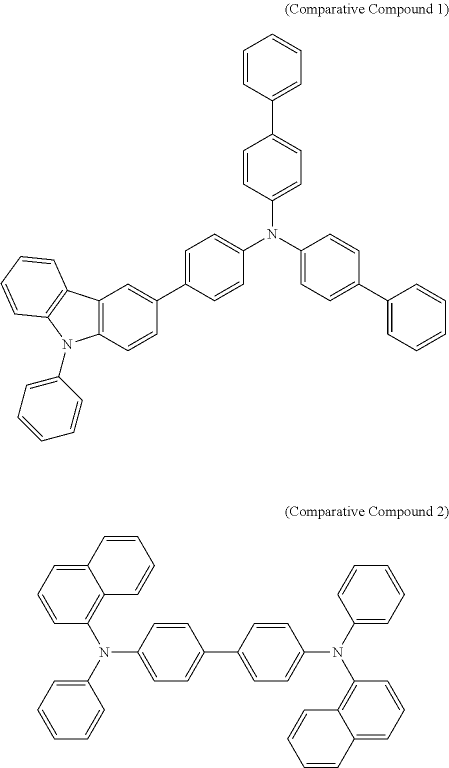 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(N(c2ccc(-c3ccc(N(c4ccccc4)c4cccc5ccccc45)cc3)cc2)c2cccc3ccccc23)cc1]

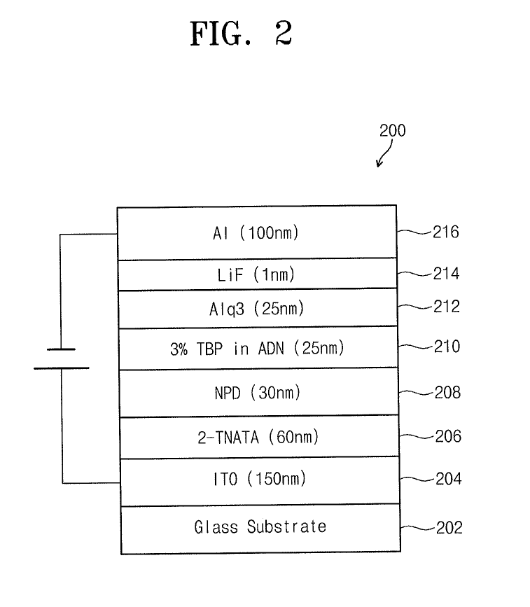

A schematic diagram of the organic EL device 200 according to Examples 1 to 4 and Comparative Examples 1 and 2 is illustrated in FIG. 2. The organic EL device 200 thus manufactured included an anode 204, a hole injection layer 206 disposed on the anode 204, a hole transport layer 208 disposed on the hole injection layer 206, an emission layer 210 disposed on the hole transport layer 208, an electron transport layer 212 and an electron injection layer 214 disposed on the emission layer 210 and a cathode 216 disposed on the electron injection layer 214.

The performance of the organic EL devices 200 according to Examples 1 to 4 and Comparative Examples 1 and 2 is illustrated in the following Table 1. For the evaluation of the electric field emission properties of the organic EL devices 200 thus manufactured, a C9920-11 luminance orientation property measuring apparatus of Hamamatsu Photonics Co. was used. In addition, the current efficiency was measured at 10 mA/cm², and the half life was measured at 1,000 cd/m².

TABLE 1

| | Hole transport | Voltage | Current efficiency | Half Life |
|---|---|---|---|---|
| | material | (V) | (cd/A) | (hr) |
| Example 1 | Compound 42 | 6.7 | 7.8 | 2,700 |
| Example 2 | Compound 16 | 7.3 | 7.4 | 2,400 |
| Example 3 | Compound 51 | 7.1 | 7.3 | 2,500 |
| Example 4 | Compound 40 | 6.4 | 7.5 | 2,500 |
| Comparative | Comparative | 7.5 | 6.2 | 1,500 |
| Example 1 | Compound 1 | | | |
| Comparative | Comparative | 8.1 | 5.3 | 1,200 |
| Example 2 | Compound 2 | | | |

As clearly shown in Table 1, the organic EL devices of Examples 1 to 4 according to embodiments were shown to have a higher efficiency and longer life when compared to those of Comparative Examples 1 and 2.

In the above-described embodiments, the organic EL device using the diamine derivative containing the octahydroanthracene group as a hole transport material has been explained. It is to be understood that the diamine derivative containing the octahydroanthracene group may be used in other emission devices or emission apparatuses. The organic EL devices shown in FIGS. 1 and 2 may be used in an organic EL display of a passive matrix driving type, or, in other implementations, may be used in an organic EL display of an active matrix driving type.

By way of summation and review, it is desirable for a hole transport layer to have good hole transport performance and carrier tolerance to improve the emission properties and to realize the long life of an organic EL device. As materials used in each layer of an organic EL device, various compounds such as an aromatic amine compound have been used. However, an organic EL device having such materials may not have sufficient emission life. Accordingly, an organic EL device that may be driven at a lower voltage and having higher efficiency and longer life is desirable.

Embodiments provide a diamine derivative to improve the life and the emission efficiency of an organic EL device, a material of an organic EL device using the diamine derivative and an organic EL device. The diamine derivative may include octahydroanthracene in the molecular structure thereof. The emission efficiency and the life of the organic EL device may be improved by using the diamine derivative in the organic EL device. In some implementations, the Since the diamine derivative having the above-described molecular structure has certain symmetry, the synthesis thereof may be relatively easy.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A diamine derivative including an octahydroanthracene group, the diamine derivative being represented by the following Formula (1): 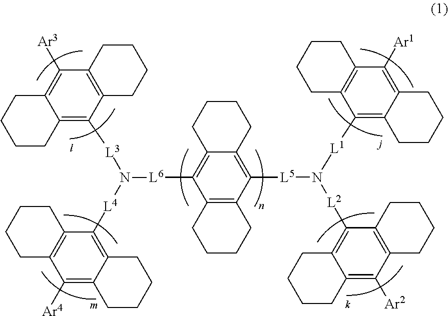
wherein, in Formula 1, Ar¹ to Ar⁴ are independently hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group or a substituted or unsubstituted trialkylsilyl group,
j, k, l, m and n are independently 0 or 1, where the relation of j+k+l+m+n≧1 is satisfied, and
L¹ to L⁶ are independently a single bond, a substituted or unsubstituted arylene group or a substituted or unsubstituted heteroarylene group.

2. The diamine derivative as claimed in claim 1, wherein the diamine derivative is represented by the following Formula (2): 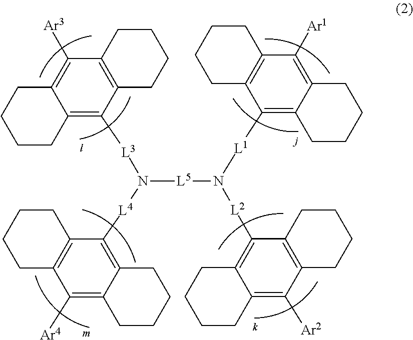
Wherein, in Formula (2), Ar¹ to Ar⁴ are hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group,
j, k, l, and m are independently 0 or 1, where the relation of j+k+l+m≧1 is satisfied, and
L¹ to L⁵ are independently a single bond, a substituted or unsubstituted aryl group or a substituted or unsubstituted heteroaryl group.

3. The diamine derivative as claimed in claim 1, wherein the diamine derivative is represented by the following Formula (3): 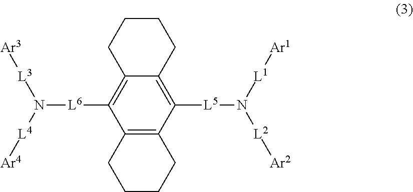
wherein, in Formula (3), Ar¹ to Ar⁴ are hydrogen, deuterium, a halogen, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group or a substituted or unsubstituted trialkylsilyl group, and
L¹ to L⁶ are independently a single bond, a substituted or unsubstituted aryl group or a substituted or unsubstituted heteroaryl group.

4. The diamine derivative as claimed in claim 1, wherein Ar¹=Ar³, Ar²=Ar⁴, L¹=L³ and L²=L⁴.

5. The diamine derivative as claimed in claim 1, wherein Ar¹=Ar², Ar³=Ar⁴, L¹=L² and L³=L⁴.

6. The diamine derivative as claimed in claim 1, wherein Ar¹=Ar²=Ar³=Ar⁴ and L¹=L²=L³=L⁴.

7. The diamine derivative as claimed in claim 6, wherein L⁵=L⁶.

8. The diamine derivative as claimed in claim 1, wherein j=l and k=m.

9. The diamine derivative as claimed in claim 1, wherein j=k and l=m.

10. The diamine derivative as claimed in claim 1, wherein Ar¹ to Ar⁴ is a substituted or unsubstituted aryl group having 6 to 18 carbon atoms, a substituted or unsubstituted carbazolyl group, a substituted or unsubstituted benzofuryl group or a substituted or unsubstituted dibenzothienyl group.

11. The diamine derivative as claimed in claim 1, wherein L¹ to L⁶ are independently a single bond or a substituted or unsubstituted aryl group having 6 to 12 carbon atoms.

12. The diamine derivative as claimed in claim 2, wherein L¹ to L⁵ are independently a single bond or a substituted or unsubstituted aryl group having 6 to 12 carbon atoms.

13. The diamine derivative as claimed in claim 1, wherein the diamine derivative is at least one represented by the following Compounds 1 to 55:

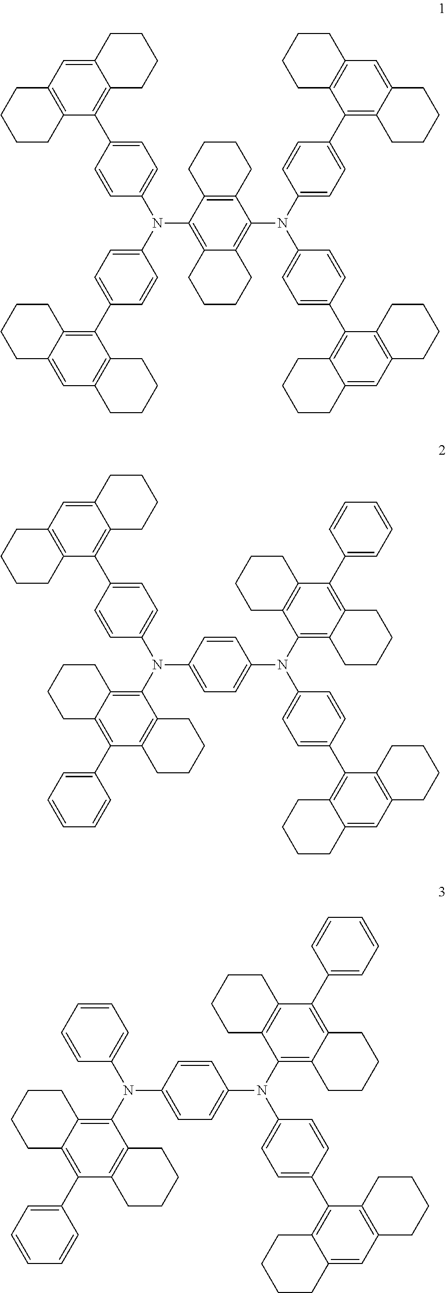 [SMILES: c1cc(N(c2ccc(-c3c4c(cc5c3CCCC5)CCCC4)cc2)c2c3c(c(N(c4ccc(-c5c6c(cc7c5CCCC7)CCCC6)cc4)c4ccc(-c5c6c(cc7c5CCCC7)CCCC6)cc4)c4c2CCCC4)CCCC3)ccc1-c1c2c(cc3c1CCCC3)CCCC2 ; c1ccc(-c2c3c(c(N(c4ccc(-c5c6c(cc7c5CCCC7)CCCC6)cc4)c4ccc(N(c5ccc(-c6c7c(cc8c6CCCC8)CCCC7)cc5)c5c6c(c(-c7ccccc7)c7c5CCCC7)CCCC6)cc4)c4c2CCCC4)CCCC3)cc1 ; c1ccc(-c2c3c(c(N(c4ccccc4)c4ccc(N(c5ccc(-c6c7c(cc8c6CCCC8)CCCC7)cc5)c5c6c(c(-c7ccccc7)c7c5CCCC7)CCCC6)cc4)c4c2CCCC4)CCCC3)cc1]

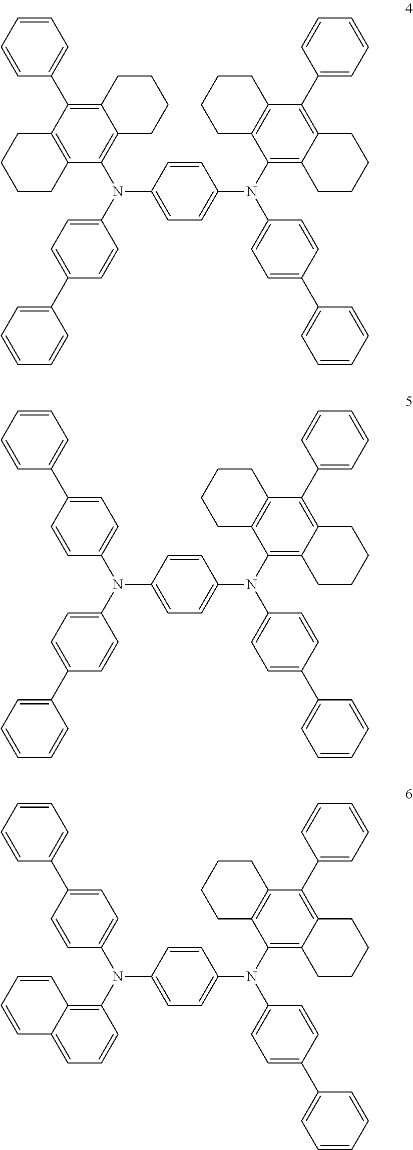

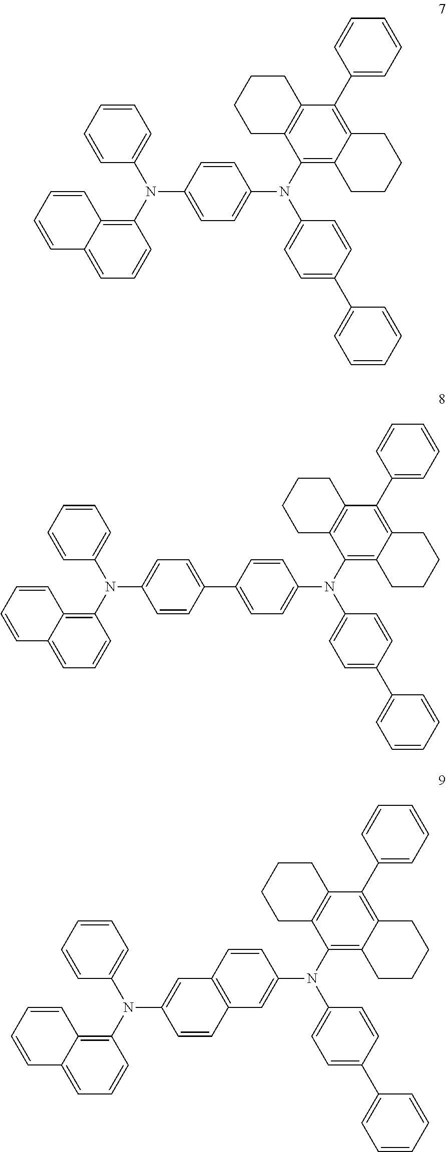 [SMILES: c1ccc(-c2ccc(N(c3ccc(N(c4ccccc4)c4cccc5ccccc45)cc3)c3c4c(c(-c5ccccc5)c5c3CCCC5)CCCC4)cc2)cc1 ; c1ccc(-c2ccc(N(c3ccc(-c4ccc(N(c5ccccc5)c5cccc6ccccc56)cc4)cc3)c3c4c(c(-c5ccccc5)c5c3CCCC5)CCCC4)cc2)cc1 ; c1ccc(-c2ccc(N(c3ccc4cc(N(c5ccccc5)c5cccc6ccccc56)ccc4c3)c3c4c(c(-c5ccccc5)c5c3CCCC5)CCCC4)cc2)cc1]

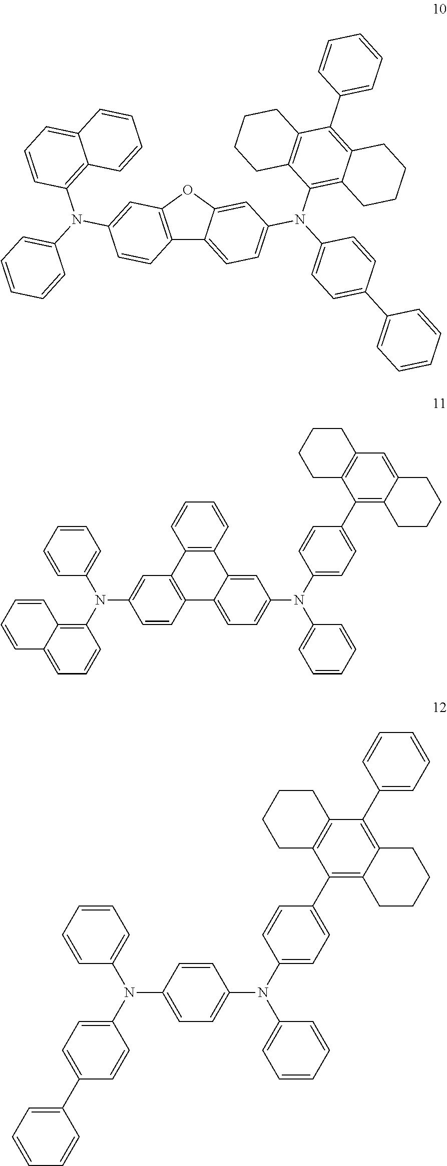 [SMILES: c1ccc(-c2ccc(N(c3ccc4c(c3)oc3cc(N(c5ccccc5)c5cccc6ccccc56)ccc34)c3c4c(c(-c5ccccc5)c5c3CCCC5)CCCC4)cc2)cc1 ; c1ccc(N(c2ccc(-c3c4c(cc5c3CCCC5)CCCC4)cc2)c2ccc3c4ccc(N(c5ccccc5)c5cccc6ccccc56)cc4c4ccccc4c3c2)cc1 ; c1ccc(-c2ccc(N(c3ccccc3)c3ccc(N(c4ccccc4)c4ccc(-c5c6c(c(-c7ccccc7)c7c5CCCC7)CCCC6)cc4)cc3)cc2)cc1]

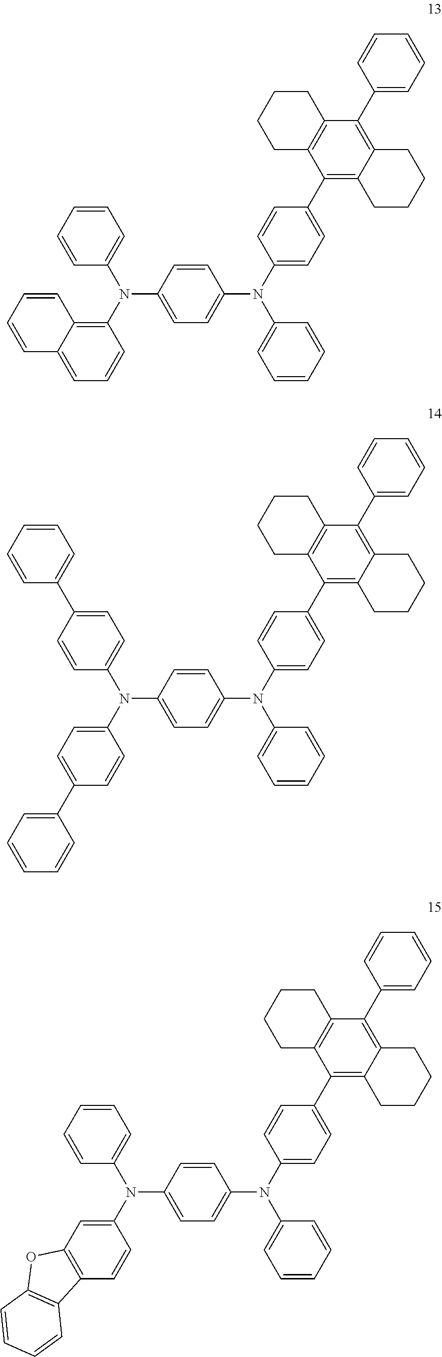 [SMILES: c1ccc(-c2c3c(c(-c4ccc(N(c5ccccc5)c5ccc(N(c6ccccc6)c6cccc7ccccc67)cc5)cc4)c4c2CCCC4)CCCC3)cc1 ; c1ccc(-c2ccc(N(c3ccc(-c4ccccc4)cc3)c3ccc(N(c4ccccc4)c4ccc(-c5c6c(c(-c7ccccc7)c7c5CCCC7)CCCC6)cc4)cc3)cc2)cc1 ; c1ccc(-c2c3c(c(-c4ccc(N(c5ccccc5)c5ccc(N(c6ccccc6)c6ccc7c(c6)oc6ccccc67)cc5)cc4)c4c2CCCC4)CCCC3)cc1]

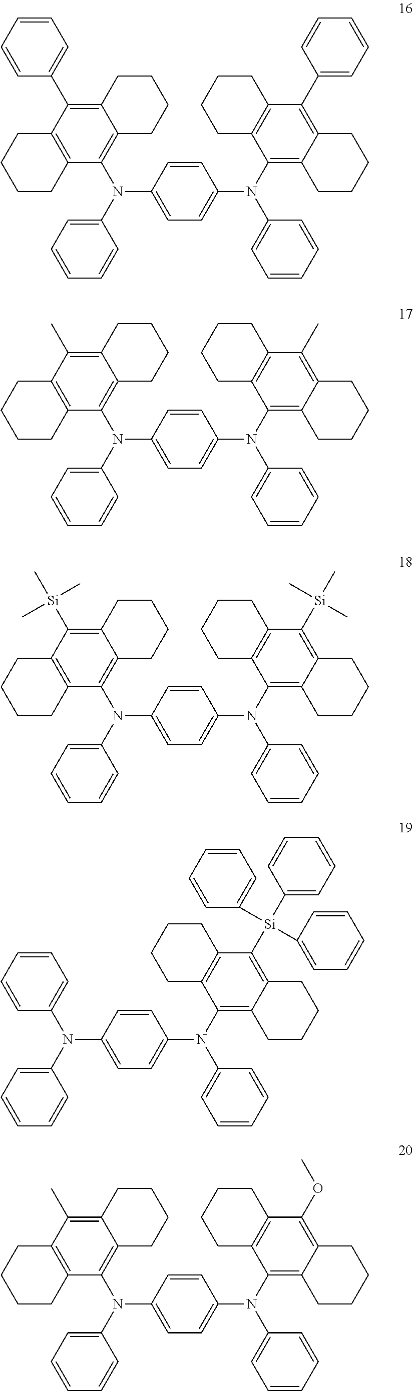

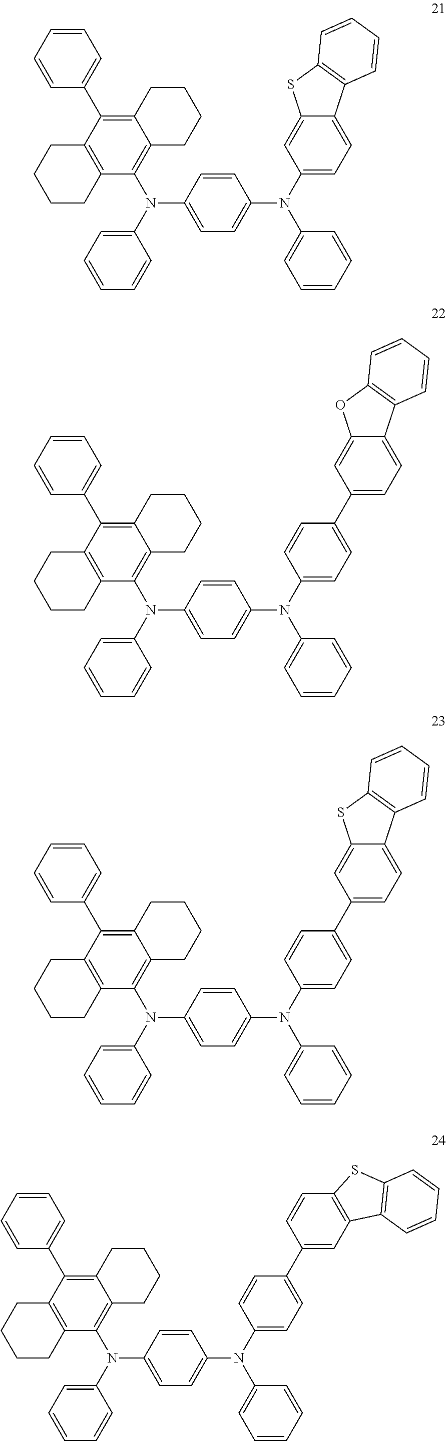 [SMILES: c1ccc(-c2c3c(c(N(c4ccccc4)c4ccc(N(c5ccccc5)c5ccc6c(c5)sc5ccccc56)cc4)c4c2CCCC4)CCCC3)cc1 ; c1ccc(-c2c3c(c(N(c4ccccc4)c4ccc(N(c5ccccc5)c5ccc(-c6ccc7c(c6)oc6ccccc67)cc5)cc4)c4c2CCCC4)CCCC3)cc1 ; c1ccc(-c2c3c(c(N(c4ccccc4)c4ccc(N(c5ccccc5)c5ccc(-c6ccc7c(c6)sc6ccccc67)cc5)cc4)c4c2CCCC4)CCCC3)cc1 ; c1ccc(-c2c3c(c(N(c4ccccc4)c4ccc(N(c5ccccc5)c5ccc(-c6ccc7sc8ccccc8c7c6)cc5)cc4)c4c2CCCC4)CCCC3)cc1]

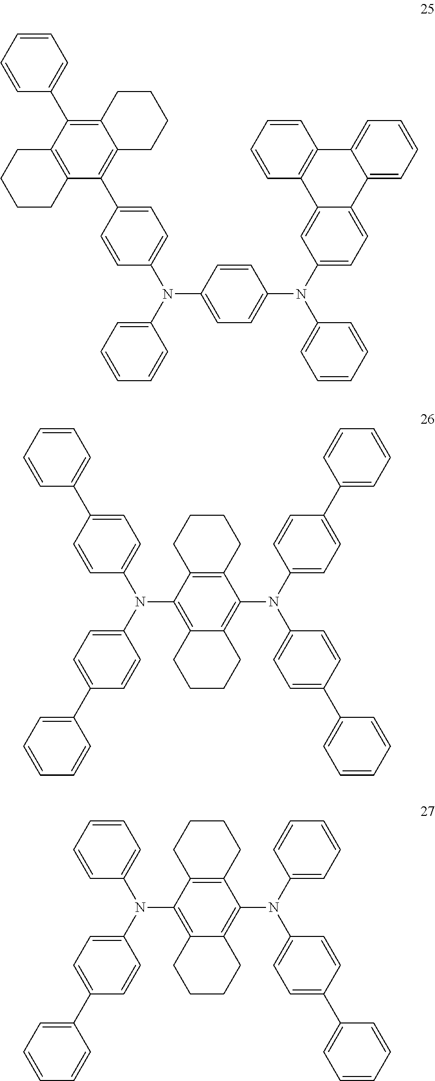 [SMILES: c1ccc(-c2c3c(c(-c4ccc(N(c5ccccc5)c5ccc(N(c6ccccc6)c6ccc7c8ccccc8c8ccccc8c7c6)cc5)cc4)c4c2CCCC4)CCCC3)cc1 ; c1ccc(-c2ccc(N(c3ccc(-c4ccccc4)cc3)c3c4c(c(N(c5ccc(-c6ccccc6)cc5)c5ccc(-c6ccccc6)cc5)c5c3CCCC5)CCCC4)cc2)cc1 ; c1ccc(-c2ccc(N(c3ccccc3)c3c4c(c(N(c5ccccc5)c5ccc(-c6ccccc6)cc5)c5c3CCCC5)CCCC4)cc2)cc1]

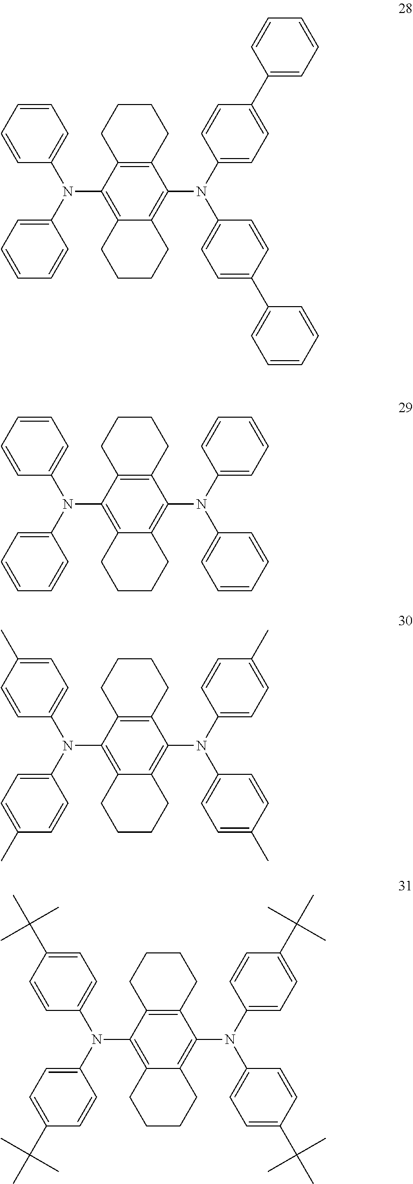

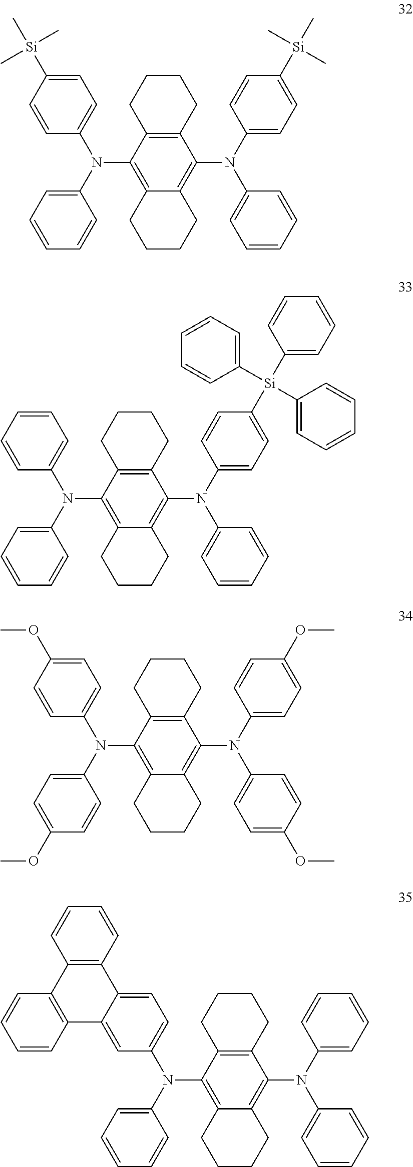

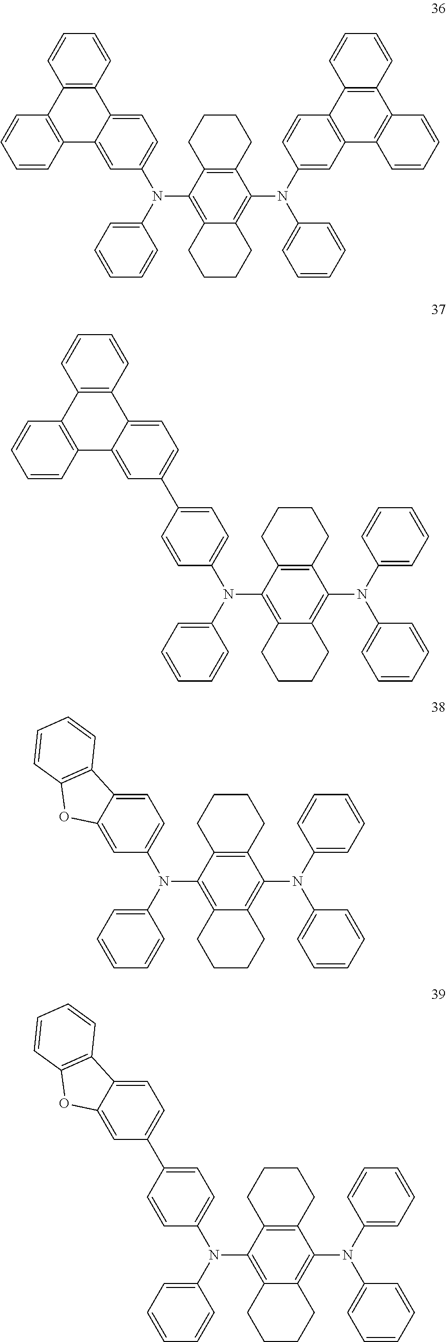 [SMILES: c1ccc(N(c2ccc3c4ccccc4c4ccccc4c3c2)c2c3c(c(N(c4ccccc4)c4ccc5c6ccccc6c6ccccc6c5c4)c4c2CCCC4)CCCC3)cc1 ; c1ccc(N(c2ccccc2)c2c3c(c(N(c4ccccc4)c4ccc(-c5ccc6c7ccccc7c7ccccc7c6c5)cc4)c4c2CCCC4)CCCC3)cc1 ; c1ccc(N(c2ccccc2)c2c3c(c(N(c4ccccc4)c4ccc5c(c4)oc4ccccc45)c4c2CCCC4)CCCC3)cc1 ; c1ccc(N(c2ccccc2)c2c3c(c(N(c4ccccc4)c4ccc(-c5ccc6c(c5)oc5ccccc56)cc4)c4c2CCCC4)CCCC3)cc1]

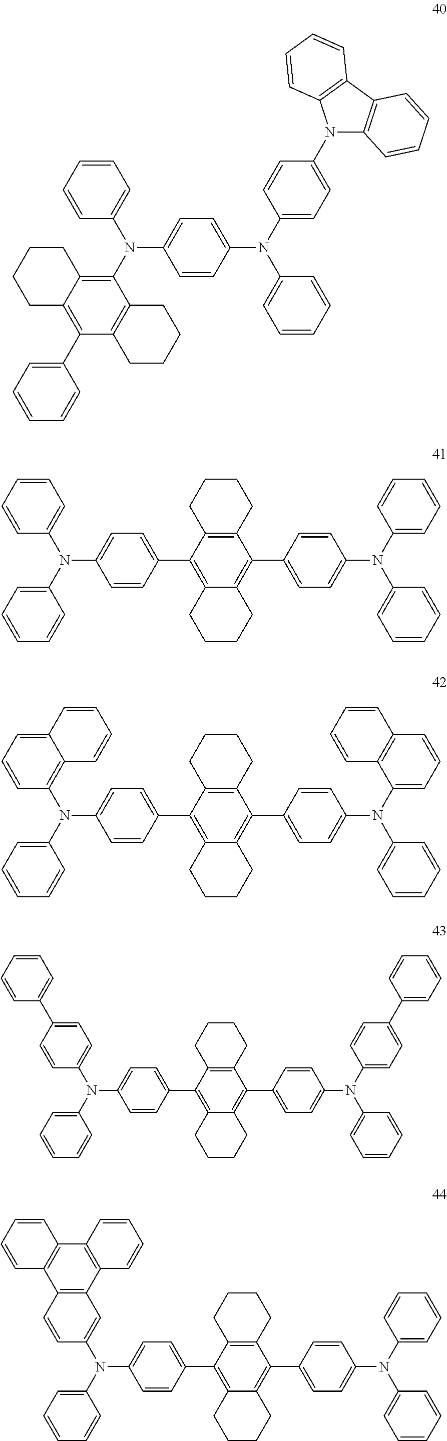

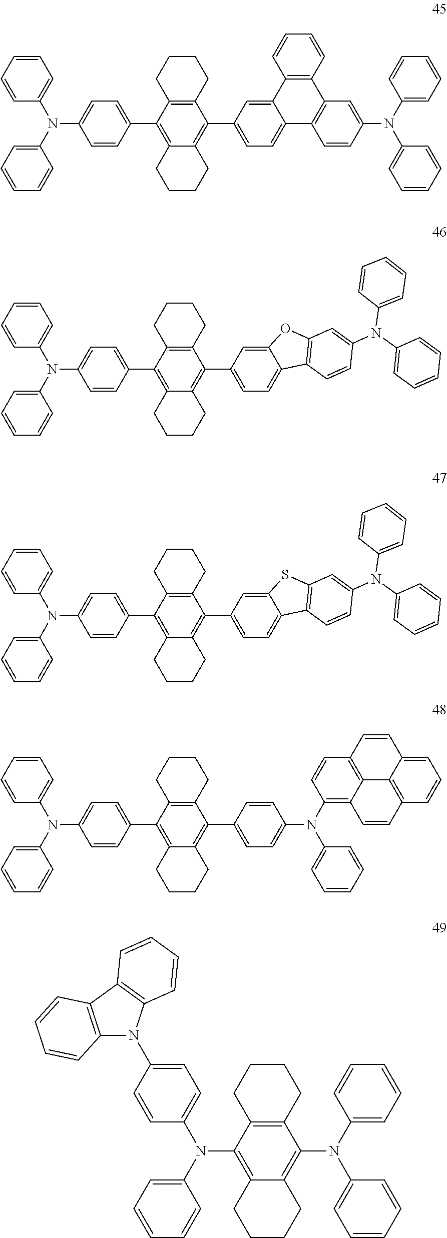

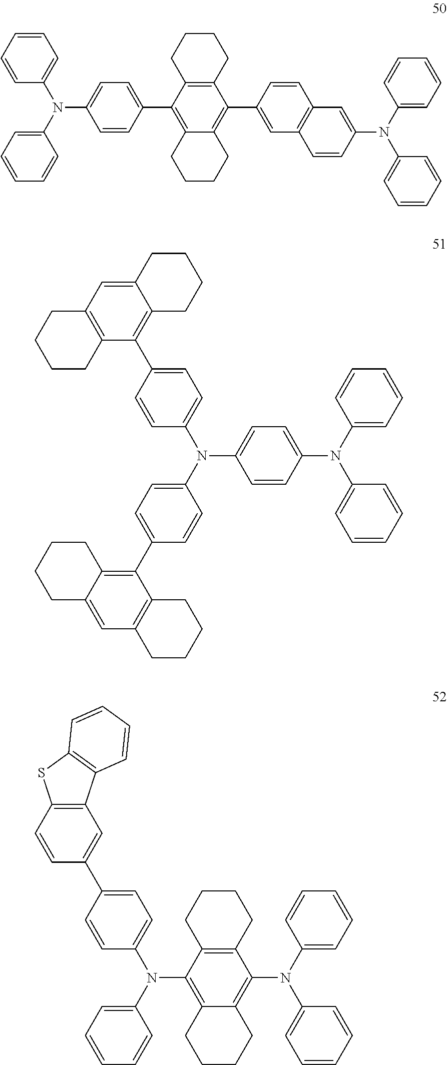 [SMILES: c1ccc(N(c2ccccc2)c2ccc(-c3c4c(c(-c5ccc6cc(N(c7ccccc7)c7ccccc7)ccc6c5)c5c3CCCC5)CCCC4)cc2)cc1 ; c1ccc(N(c2ccccc2)c2ccc(N(c3ccc(-c4c5c(cc6c4CCCC6)CCCC5)cc3)c3ccc(-c4c5c(cc6c4CCCC6)CCCC5)cc3)cc2)cc1 ; c1ccc(N(c2ccccc2)c2c3c(c(N(c4ccccc4)c4ccc(-c5ccc6sc7ccccc7c6c5)cc4)c4c2CCCC4)CCCC3)cc1]

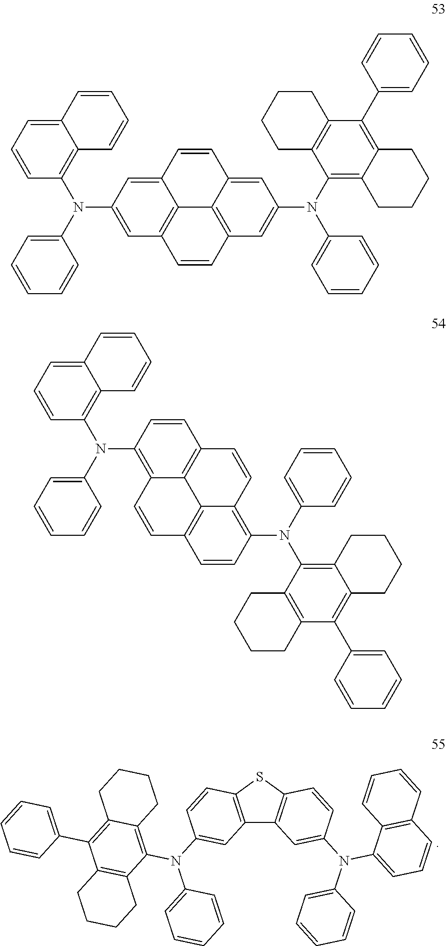 [SMILES: c1ccc(-c2c3c(c(N(c4ccccc4)c4cc5ccc6cc(N(c7ccccc7)c7cccc8ccccc78)cc7ccc(c4)c5c67)c4c2CCCC4)CCCC3)cc1 ; c1ccc(-c2c3c(c(N(c4ccccc4)c4ccc5ccc6c(N(c7ccccc7)c7cccc8ccccc78)ccc7ccc4c5c76)c4c2CCCC4)CCCC3)cc1 ; c1ccc(-c2c3c(c(N(c4ccccc4)c4ccc5sc6ccc(N(c7ccccc7)c7cccc8ccccc78)cc6c5c4)c4c2CCCC4)CCCC3)cc1]

14. A material for an organic electroluminescence (EL) device comprising the diamine derivative as claimed in claim 1.

15. The material for an organic EL device as claimed in claim 14, wherein the material is a hole transport material.

16. An organic electroluminescence (EL) device comprising the diamine derivative as claimed in claim 1 in a layer of stacked layers between an emission layer and an anode.
